(19) United States
(12) Patent Application Publication
(10) Pub. No.: US 2026/0164753 A1
(43) Pub. Date: Jun. 11, 2026

(54) INTEGRATED CIRCUIT DEVICE

(71) Applicant: SAMSUNG ELECTRONICS CO., LTD., Suwon-si (KR)

(72) Inventor: Myoungsoo KIM, Suwon-si (KR)

(73) Assignee: SAMSUNG ELECTRONICS CO., LTD., Suwon-si (KR)

(21) Appl. No.: 19/183,381

(22) Filed: Apr. 18, 2025

Related U.S. Application Data
(63) Continuation-in-part of application No. 19/083,498, filed on Mar. 19, 2025.

(30) Foreign Application Priority Data
Sep. 11, 2024 (KR) 10-2024-0124242
Mar. 7, 2025 (KR) 10-2025-0029955

(51) Int. Cl. H10D 64/27; H10D 30/60

(52) U.S. Cl. CPC H10D 64/519; H10D 30/601; H10D 64/513

(57) ABSTRACT

An integrated circuit device includes a substrate having an active region defined by a device isolation film, and a gate electrode disposed over the active region so as to be spaced apart from the device isolation film, wherein the gate electrode has a closed-loop shape in a plan view.

### CROSS-REFERENCE TO RELATED APPLICATION

This is a Continuation-in-part of U.S. patent application Ser. No. 19/083,498, filed on Mar. 19, 2025, which claims priority under 35 U.S.C. § 119 to Korean Patent Application No. 10-2024-0124242, filed on Sep. 11, 2024 and Korean Patent Application No. 10-2025-0029955 filed on Mar. 7, 2025, in the Korean Intellectual Property Office, the disclosure of which is incorporated by reference in its entirety herein.

### 1. Technical Field

Embodiments of the inventive concept are directed to an integrated circuit device, and more particularly, to an integrated circuit device including a transistor.

### 2. Discussion of Related Art

An integrated circuit (IC) is a miniaturized electronic circuit consisting of multiple interconnected components such as transistors, resistors, capacitors, and diodes, all fabricated on a single semiconductor substrate (usually silicon). ICs are designed to perform various functions, including signal processing, computation, amplification, and power management. An integrated circuit device may include one or more ICs.

As the electronics industry has advanced, the integration level of integrated circuit devices has progressively increased. Consequently, optimized designs are needed to enhance the reliability of integrated circuit devices while minimizing their footprint. Display driver integrated circuits (DDIs) for driving display devices, such as liquid-crystal display devices (LCDs) or plasma display panels (PDPs) are examples of integrated circuit devices. DDIs include transistors with a wide range of operating voltages.

DDIs include high-voltage transistors operating at relatively high operating voltages. Transistors typically occupy a large area due to the need for extended drift regions, thicker gate oxides, and longer channel lengths to sustain high operating voltages while preventing breakdown. Additionally, these transistors often exhibit a hump phenomenon in their transfer characteristics, which arises from unintended edge channels forming near the interface between the device isolation region and the active region. These parasitic conduction paths can lead to an unexpected increase in drain current, affecting device performance and reliability. Furthermore, high-voltage transistors are susceptible to threshold voltage variations due to process fluctuations, charge trapping at the isolation interface, and hot carrier effects, which can degrade performance over time.

### SUMMARY

The inventive concept provides an integrated circuit device with the intended performance with a minimum area in a highly reduced area by reducing an occupied area of a transistor as well as by preventing the formation of an unintended edge channel in the vicinity of an interface between a device isolation region and an active region in the transistor and preventing a reduction in threshold voltage through the suppression of a hump phenomenon.

According to an aspect of the inventive concept, there is provided an integrated circuit device including a substrate including an active region defined by a device isolation film, and a gate electrode disposed over the active region so as to be apart from the device isolation film, wherein the gate electrode has a closed-loop shape in a plan view.

According to another aspect of the inventive concept, there is provided an integrated circuit device including a substrate including an active region defined by a device isolation film, and a transistor disposed on the active region, wherein the transistor includes a first source/drain region disposed in a first active region that is a portion of the active region, a gate electrode having a closed-loop shape surrounding the first source/drain region in a plan view, and a second source/drain region, which has a closed-loop shape surrounding the gate electrode and the first source/drain region in a plan view and is disposed in a second active region of the active region, the second active region being spaced apart from the first active region.

According to another aspect of the inventive concept, there is provided an integrated circuit device including a substrate including an active region defined by a device isolation film, a gate electrode disposed over the active region and spaced apart from the device isolation film in a horizontal direction not to overlap the device isolation film in a vertical direction, a first source/drain region disposed in a first active region, which is a portion of the active region, and surrounded by the gate electrode in a plan view, a second source/drain region disposed in a second active region of the active region and spaced apart from the first source/drain region with the gate electrode therebetween in a plan view, the second active region being spaced apart from the first active region, a channel region disposed in the active region between the first source/drain region and the second source/drain region, wherein each of the gate electrode, the second source/drain region, and the channel region has a closed-loop shape in a plan view.

According to another aspect of the inventive concept, there is provided a method of fabricating an integrated circuit device, the method including defining an active region in a substrate, forming a gate electrode over the active region, the gate electrode having a closed-loop shape in a plan view, and forming a first source/drain region in a first active region of the active region and forming a second source/drain region in a second active region of the active region, the first active region being surrounded by the gate electrode in a plan view, and the second active region being between the gate electrode and the device isolation film in a plan view.

In some embodiments, the second source/drain region may have a closed-loop shape surrounding the gate electrode and the first source/drain region in a plan view.

In some embodiments, each of the first source/drain region and the second source/drain region may include a lightly-doped region and a heavily-doped region that is surrounded by the lightly-doped region, and at least one of the first source/drain region and the second source/drain region may include a drift region in the lightly-doped region, the drift region extending in a horizontal direction from the heavily-doped region toward the gate electrode.

In some embodiments, each of the first source/drain region and the second source/drain region may include a lightly-doped region, a heavily-doped region surrounded by the lightly-doped region, and a drift region extending in a horizontal direction from the heavily-doped region toward the gate electrode. In some embodiments, the drift region may have a closed-loop shape in a plan view.

In some embodiments, the method may further include, before the forming of the gate electrode, forming a recess trench in the active region by partially etching the substrate in the active region from a main surface of the substrate, and forming a gate dielectric film to conformally cover an inner wall of the recess trench, wherein the forming of the gate electrode may include forming a gate electrode layer to cover the gate dielectric film in the recess trench and cover the substrate outside the recess trench, and patterning the gate electrode.

In some embodiments, the method may further include, before the forming of the gate electrode, forming a gate dielectric film on a main surface of the substrate to cover the active region, wherein, in the forming of the gate electrode, the gate electrode may be formed on the gate dielectric film to cover the active region.

In some embodiments, in the forming of the gate electrode, the gate electrode may have a quadrangular closed-loop shape with rounded corners, an elliptical closed-loop shape, or a circular closed-loop shape in a plan view.

In some embodiments, each of the first source/drain region and the second source/drain region may include a lightly-doped region and a heavily-doped region that is surrounded by the lightly-doped region, the lightly-doped region of each of the first source/drain region and the second source/drain region may be formed before the forming of the gate electrode, and the heavily-doped region of each of the first source/drain region and the second source/drain region may be formed after the forming of the gate electrode.

In some embodiments, the method may further include, after the first source/drain region and the second source/drain region are formed, forming a plurality of metal silicide films to cover an upper surface of the gate electrode, an upper surface of the first source/drain region, and an upper surface of the second source/drain region, wherein a portion, which covers the upper surface of the second source/drain region, of the plurality of metal silicide films may have a closed-loop shape in a plan view.

### BRIEF DESCRIPTION OF THE DRAWINGS

Embodiments will be more clearly understood from the following detailed description taken in conjunction with the accompanying drawings in which:

FIG. 1A is a planar layout diagram illustrating an integrated circuit device according to an embodiment;

FIG. 1B is a cross-sectional view of the integrated circuit device of FIG. 1A, taken along a line X1-X1′ of FIG. 1A;

FIG. 2 is a cross-sectional view illustrating an integrated circuit device according to an embodiment;

FIG. 3A is a planar layout diagram illustrating an integrated circuit device according to some embodiments;

FIG. 3B is a cross-sectional view of the integrated circuit device of FIG. 3A, taken along a line X1-X1′ of FIG. 3A;

FIG. 4A is a planar layout diagram illustrating an integrated circuit device according to some embodiments;

FIG. 4B is a cross-sectional view of the integrated circuit device of FIG. 4A, taken along a line X1-X1′ of FIG. 4A;

FIG. 5 is a cross-sectional view illustrating an integrated circuit device according to an embodiment;

FIGS. 6, 7, and 8 are planar layout diagrams each illustrating an integrated circuit device according to some embodiments;

FIG. 9 is a planar layout diagram illustrating an integrated circuit device according to an embodiment;

FIG. 10A is a planar layout diagram illustrating an integrated circuit device according to an embodiment;

FIG. 10B is a cross-sectional view of the integrated circuit device of FIG. 8A, taken along a line X7-X7′ of FIG. 10A;

FIG. 11 is a planar layout diagram illustrating an integrated circuit device according to an embodiment;

FIG. 12 is a planar layout diagram illustrating an integrated circuit device according to an embodiment;

FIG. 13A is a planar layout diagram illustrating an integrated circuit device according to some embodiments;

FIG. 13B is a cross-sectional view of the integrated circuit device of FIG. 13A, taken along a line X1-X1′ of FIG. 13A;

FIG. 14A is a planar layout diagram illustrating an integrated circuit device according to some embodiments;

FIG. 14B is a cross-sectional view of the integrated circuit device of FIG. 14A, taken along a line X1-X1′ of FIG. 14A;

FIG. 15A is a planar layout diagram illustrating an integrated circuit device according to some embodiments;

FIG. 15B is a cross-sectional view of the integrated circuit device of FIG. 15A, taken along a line X1-X1′ of FIG. 15A;

FIG. 16 a cross-sectional view illustrating an integrated circuit device according to some embodiments;

FIG. 17 is a schematic block diagram of a display device according to an embodiment;

FIGS. 18A to 18G are cross-sectional views respectively illustrating a sequence of processes of a method of fabricating an integrated circuit device, according to an embodiment; and

FIGS. 19A to 19E are cross-sectional views respectively illustrating a sequence of processes of a method of fabricating an integrated circuit device, according to some embodiments.

### DETAILED DESCRIPTION

Embodiments of the inventive concept relate to an integrated circuit (IC) device featuring a recess channel transistor designed to enhance performance while minimizing chip area. The transistor includes a recess trench formed in the active region of a substrate, spaced apart from the device isolation film, and extending vertically into the substrate. A gate electrode, positioned within the recess trench, has a closed-loop shape in a plan view, which helps enhance threshold voltage stability and suppresses unintended edge channels that can degrade performance. The design also incorporates source/drain regions and a gate dielectric film to ensure reliable transistor operation.

Additionally, some embodiments include a pocket well and a deep well of different conductivity types to provide enhanced electrical isolation and high-voltage operation. The gate electrode consists of a buried electrode portion within the recess trench and a protruding electrode portion extending above the substrate surface, optimizing gate control. By preventing overlap with the device isolation film, the design reduces leakage current, enhances transistor reliability, and enables efficient scaling for display driver ICs and other semiconductor applications.

Hereinafter, embodiments of the inventive concept will be described in detail with reference to the accompanying drawings. Like components are denoted by like reference numerals throughout the specification, and repeated descriptions thereof are omitted.

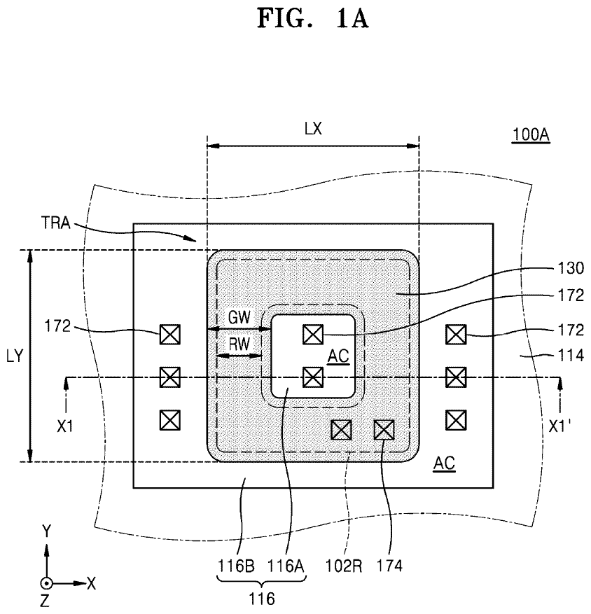

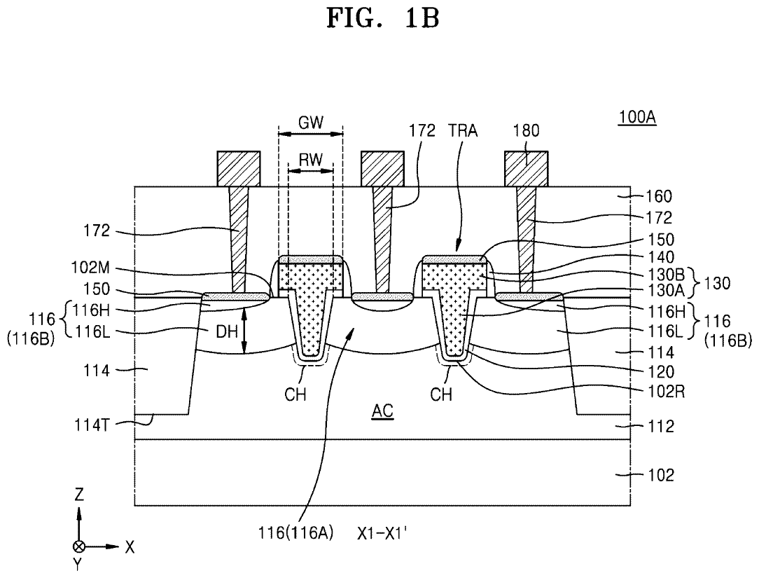

FIG. 1A is a planar layout diagram illustrating an integrated circuit device 100A according to an embodiment. FIG. 1B is a cross-sectional view of the integrated circuit device 100A, taken along line X1-X1′ of FIG. 1A.

Referring to FIGS. 1A and 1B, the integrated circuit device 100A may include a substrate 102 including a well 112, a device isolation film 114 buried in a portion of the substrate 102 in an area defined by the well 112, and an active region AC defined in the substrate 102 by the device isolation film 114. The device isolation film 114 may fill a trench region 114T formed in the substrate 102. The device isolation film 114 may include a silicon oxide film.

The substrate 102 may include a semiconductor substrate. In some embodiments, the substrate 102 may include a semiconductor, such as Silicon (Si) or Germanium (Ge). In some embodiments, the substrate 102 may include a compound semiconductor, such as Silicon-Germanium (SiGe), Silicon Carbide (SiC), Gallium Arsenide (GaAs), Indium Arsenide (InAs), or Indium Phosphide (InP).

A recess channel transistor TRA may be arranged on the active region AC. In some embodiments, the recess channel transistor TRA is a high-voltage transistor operated by a relatively high power-supply voltage of about 5 V to about 200 V, but is not limited thereto.

A recess trench 102R may be arranged in the active region AC to be spaced apart from the device isolation film 114. In FIG. 1A, a planar shape of the recess trench 102R is shown by a dashed line. The recess trench 102R may include an inner space extending in a vertical direction (a Z direction) from a main surface 102M of the substrate 102 toward the inside of the substrate 102 or towards an interior of the substrate 102. The recess channel transistor TRA may be configured such that a channel thereof is formed or positioned along a surface of the recess trench 102R. The recess channel transistor TRA may include a channel region CH arranged in the well 112 to be adjacent to the bottom of the recess trench 102R.

In an embodiment, the recess channel transistor TRA includes a gate dielectric film 120, which covers an inner wall of the recess trench 102R, and a gate electrode 130 arranged on the gate dielectric film 120. The inner space of the recess trench 102R may be filled with the gate dielectric film 120 and the gate electrode 130. As shown in FIG. 1B, the gate electrode 130 may include a buried electrode portion 130A, which is arranged on the gate dielectric film 120 to fill the recess trench 102R, and a protruding electrode portion 130B, which is integrally connected to the buried electrode portion 130A and protrudes above the main surface 102M of the substrate 102. For example, the gate electrode 130 may include a buried electrode portion 130A, positioned on the gate dielectric film 120 and occupying the recess trench 102R, along with a protruding electrode portion 130B, which is seamlessly connected to the buried electrode portion 130A and extends above the main surface 102M of the substrate 102.

In an embodiment, the gate dielectric film 120 includes a silicon oxide film and the gate electrode 130 includes a doped polysilicon film. The doped polysilicon film constituting the gate electrode 130 may be doped with a p-type or n-type impurity according to a channel type of the recess channel transistor TRA. For example, when the recess channel transistor TRA includes a P-channel Metal-Oxide-Semiconductor (PMOS) transistor, the gate electrode 130 may include a polysilicon film doped with a p-type impurity, and when the recess channel transistor TRA includes a N-channel Metal-Oxide-Semiconductor (NMOS) transistor, the gate electrode 130 may include a polysilicon film doped with an n-type impurity.

In a plan view, the active region AC may include a local region (which may be referred to as a first active region) surrounded by the recess trench 102R and the gate electrode 130, and a local region (which may be referred to as a second active region) arranged between the device isolation film 114 and both of the recess trench 102R and the gate electrode 130. As used herein, the term “plan view” refers to a point of view from the X-Y plane in the accompanying drawings. The recess channel transistor TRA may include a plurality of source/drain regions 116 that are spaced apart from each other with the gate electrode 130 therebetween. The plurality of source/drain regions 116 may be arranged in the well 112.

As shown in FIG. 1A, the plurality of source/drain regions 116 may include a first source/drain region 116A and a second source/drain region 116B, which are apart from each other with the gate electrode 130 therebetween. The first source/drain region 116A may be arranged in the local region (the first active region), which is surrounded by the recess trench 102R and the gate electrode 130 in a plan view, of the active region AC. The second source/drain region 116B may be arranged in the local region (the second active region), which is between the device isolation film 114 and both of the recess trench 102R and the gate electrode 130 in a plan view, of the active region AC. In a plan view, the second source/drain region 116B may surround the first source/drain region 116A and the gate electrode 130. In the plurality of source/drain regions 116, when the first source/drain region 116A operates as a source, the second source/drain region 116B may operate as a drain. In the plurality of source/drain regions 116, when the first source/drain region 116A operates as a drain, the second source/drain region 116B may operate as a source.

The gate dielectric film 120 may include a first portion, which is disposed between the gate electrode 130 and each of the plurality of source/drain regions 116, and a second portion adjacent to the channel region CH. In an embodiments of the gate dielectric film 120, the thickness of the first portion is greater than the thickness of the second portion. Therefore, the thickness of the gate dielectric film 120 may decrease away from the main surface 102M of the substrate 102 in the vertical direction (the Z direction). In an embodiment, the gate dielectric film 120 covering the inner wall of the recess trench 102R covers the gate electrode 130 with a constant thickness, and thus, in the gate dielectric film 120, the thickness of the first portion may be substantially equal to the thickness of the second portion.

The integrated circuit device 100A may include an insulating spacer 140 covering sidewalls of the gate electrode 130. The insulating spacer 140 may include a portion vertically overlapping the plurality of source/drain regions 116. In some embodiments, the insulating spacer 140 may include a silicon oxide film, a silicon nitride film, or a combination thereof.

As shown in FIG. 1B, each of the plurality of source/drain regions 116 may include a lightly-doped region 116L and a heavily-doped region 116H that is self-aligned by the insulating spacer 140. For example, the heavily-doped region 116H may be formed in alignment with the edges of the insulating spacer 140, ensuring precise positioning relative to the gate structure. The heavily-doped region 116H may have an impurity concentration that is higher than the impurity concentration in the lightly-doped region 116L.

The well 112 may surround the plurality of source/drain regions 116. The well 112 may include an impurity-doped region of a first conductivity type, and the plurality of source/drain regions 116 may each include an impurity-doped region of a second conductivity type that is opposite to the first conductivity type. In some embodiments, the first conductivity type may be an n-type and the second conductivity type may be a p-type. In some embodiments, the first conductivity type may be a p-type and the second conductivity type may be an n-type.

As shown in FIG. 1A, in a plan view, each of the recess trench 102R and the gate electrode 130 may have a closed-loop shape. As used herein, the term “closed loop” refers to a structure in which a ring with an arbitrary shape continuously extends without breaking. Because the channel region CH is arranged along the gate electrode 130 so as to be adjacent to a bottom portion of the recess trench 102R, the channel region CH may also have a closed-loop shape in a plan view, similar to the recess trench 102R and the gate electrode 130.

In addition, the second source/drain region 116B disposed between the recess trench 102R and the device isolation film 114, among the plurality of source/drain regions 116, may have a closed-loop shape surrounding the recess trench 102R and the gate electrode 130, in a plan view.

In some embodiments, the gate electrode 130 may have a quadrangular closed-loop shape with rounded corners, in a plan view. For example, the gate electrode 130 may have a square closed-loop shape with rounded corners. In this case, in a plan view, a first length LX of the gate electrode 130 in a first horizontal direction (an X direction) may be equal to or substantially equal to a second length LY of the gate electrode 130 in a second horizontal direction (a Y direction) that is orthogonal to the first horizontal direction (the X direction). In some embodiments, the gate electrode 130 may have a rectangular closed-loop shape with rounded corners, in a plan view. In this case, in a plan view, the first length LX of the gate electrode 130 in the first horizontal direction (the X direction) may be different from the second length LY of the gate electrode 130 in the second horizontal direction (the Y direction) that is orthogonal to the first horizontal direction (the X direction).

As shown in FIGS. 1A and 1B, in a width direction of the gate electrode 130, according to an embodiment, a first width GW of the protruding electrode portion 130B of the gate electrode 130 is greater than a second width RW of the recess trench 102R. Herein, the width direction of the gate electrode 130 refers to a direction that is orthogonal to a length direction that is along a path of a closed loop including the gate electrode 130. When the first width GW of the protruding electrode portion 130B of the gate electrode 130 is greater than the second width RW of the recess trench 102R, the protruding electrode portion 130B of the gate electrode 130 may include a portion located outside the recess trench 102R to overlap the main surface 102M of the substrate 102 in the vertical direction (the Z direction). For example, if the first width GW of the protruding electrode portion 130B of the gate electrode 130 exceeds the second width RW of the recess trench 102R, a portion of the protruding electrode portion 130B may extend beyond the boundaries of the recess trench 102R, overlapping the main surface 102M of the substrate 102 in the vertical direction.

In a plan view, each of the buried electrode portion 130A and the protruding electrode portion 130B of the gate electrode 130 may be apart from the device isolation film 114 in a horizontal direction (for example, the X direction and the Y direction) with a sufficient distance therebetween not to overlap the device isolation film 114 in the vertical direction (the Z direction). For example, the buried electrode portion 130A and the protruding electrode portion 130B may remain entirely within the active region AC without extending over the device isolation film 114. As shown in FIGS. 1A and 1B, in the horizontal direction (for example, the X direction and the Y direction), the gate electrode 130 may be arranged to be sufficiently apart from the device isolation film 114 with the second source/drain region 116B therebetween, the second source/drain region 116B being one of the plurality of source/drain regions 116.

An upper surface of the gate electrode 130 and upper surfaces of the plurality of source/drain regions 116 may each be covered by a metal silicide film 150. Each of the metal silicide film 150 covering the upper surface of the gate electrode 130 and the metal silicide film 150 covering the second source/drain region 116B from among the plurality of source/drain regions 116 may have a closed-loop shape in a plan view.

In some embodiments, the metal silicide film 150 may include, but is not limited to, titanium (Ti) silicide, cobalt (Co) silicide, or nickel (Ni) silicide.

In an embodiment, the device isolation film 114 and the recess channel transistor TRA disposed on the substrate 102 are covered by an interlayer dielectric 160. The interlayer dielectric 160 may include an oxide film, a nitride film, or a combination thereof.

The integrated circuit device 100A may further include a plurality of source/drain contact plugs 172, which are connected to the heavily-doped regions 116H of the plurality of source/drain regions 116, and a plurality of gate contact plugs 174, which pass through the interlayer dielectric 160 and are connected to the gate electrode 130. Each of the plurality of source/drain contact plugs 172 may be connected to a heavily-doped region 116H of a source/drain region 116 via the metal silicide film 150. Each of the plurality of gate contact plugs 174 may be connected to the protruding electrode portion 130B of the gate electrode 130 via the metal silicide film 150. In some embodiments, the plurality of source/drain contact plugs 172 and the plurality of gate contact plugs 174 may each include a stack structure of a conductive barrier film and a metal plug. In the plurality of source/drain contact plugs 172 and the plurality of gate contact plugs 174, the conductive barrier film may include Ti, TiN, or a combination thereof and the metal plug may include tungsten (W), but the inventive concept is not limited thereto.

A plurality of wiring layers 180 may be arranged on the interlayer dielectric 160. The plurality of source/drain contact plugs 172 and the plurality of gate contact plugs 174 may each be connected to each one wiring layer 180 selected from the plurality of wiring layers 180. Each of the plurality of wiring layers 180 may include a stack structure of a conductive barrier film and a metal plug. In the plurality of wiring layers 180, the conductive barrier film may include Titanium (Ti), Titanium Nitride (TiN), or a combination thereof and the metal plug may include aluminum (Al), but the inventive concept is not limited thereto.

A high-voltage transistor may operate at a relatively high voltage. It may have a structure where the gate electrode is arranged adjacent to a device isolation film that defines an active region. Alternately, a portion of the gate electrode may extend over an upper surface of the device isolation film to overlap the device isolation film in a vertical direction. In such structures, a semiconductor fence may unintentionally form. This semiconductor fence, for example, a silicon fence, is a portion of the active region. The fence may appear between the gate electrode and the device isolation film, potentially affecting the device's performance. In this case, even when a voltage lower than a threshold voltage is applied to the gate electrode, channel inversion may easily occur in the vicinity of the silicon fence. As a result, an edge channel may be formed at a voltage lower than the threshold voltage in the vicinity of the silicon fence, thereby causing a hump phenomenon. When such a hump phenomenon occurs, it can lead to threshold voltage degradation in a transistor due to the formation of a parasitic transistor, an increase in leakage current at or below the threshold voltage, and inconsistent threshold voltage variations among transistors within the chip, potentially resulting in malfunctions.

In the recess channel transistor TRA of the integrated circuit device 100A described with reference to FIGS. 1A and 1B, by designing the buried electrode portion 130A, which fills the recess trench 102R, of the gate electrode 130 to have a sufficiently great length in the vertical direction (the Z direction), the channel length of the recess channel transistor TRA may be increased, thereby reducing an off-current. In addition, in the integrated circuit device 100A, by designing the buried electrode portion 130A, which fills the recess trench 102R, of the gate electrode 130 to have a sufficiently great length in the vertical direction (the Z direction), because a vertical-direction (Z-direction) length DH of the lightly-doped region 116L of the source/drain region 116 may be sufficiently secured, a sufficient depletion region may be secured in the recess channel transistor TRA. Thus, a voltage-resistant effect of the recess channel transistor TRA may be maximized.

Furthermore, the recess channel transistor TRA includes the gate electrode 130 arranged in the active region AC to be sufficiently spaced apart from the device isolation film 114 with the second source/drain region 116B disposed therebetween, the second source/drain region 116B being one of the plurality of source/drain regions 116, and the gate electrode 130 has a closed-loop shape in a plan view. Therefore, according to the integrated circuit device 100A of the inventive concept, an occupied area of a high-voltage transistor including the recess channel transistor TRA may be reduced, and a hump phenomenon due to the formation of an unintended edge channel in the recess channel transistor TRA may be prevented. In addition, the integrated circuit device 100A may have a structure that effectively reduces threshold voltage variations among transistors in a chip, and increases the effective gate length of the recess channel transistor TRA. Therefore, the integrated circuit device 100A according to the inventive concept may achieve the intended performance with a minimum area in a reduced area and may provide excellent reliability.

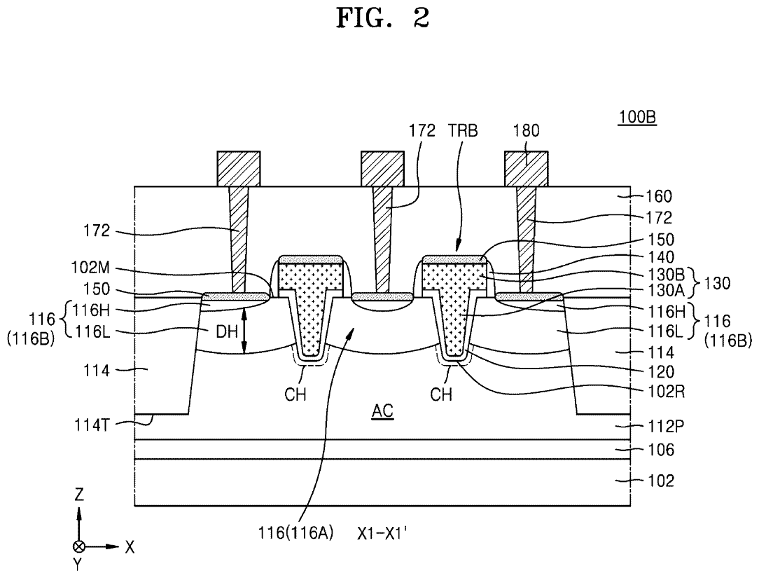

FIG. 2 is a cross-sectional view illustrating an integrated circuit device 100B according to an embodiment. FIG. 2 illustrates a cross-sectional configuration of a portion of the integrated circuit device 100B, the portion corresponding to the cross-section taken along the line X1-X1′ of FIG. 1A. In FIG. 2, the same reference numerals as in FIGS. 1A and 1B respectively denote the same members, and here, repeated descriptions thereof are omitted.

Referring to FIG. 2, the integrated circuit device 100B has substantially the same configuration as the integrated circuit device 100A shown in FIGS. 1A and 1B. However, the integrated circuit device 100B includes a recess channel transistor TRB having a triple well structure. The integrated circuit device 100B includes a pocket well 112P of a first conductivity type, which accommodates the recess trench 102R constituting the recess channel transistor TRB, and a deep well 106 of a second conductivity type, which accommodates the pocket well 112P. The triple well includes: the pocket well 112P providing local doping control for the transistor; the deep well 106 serving as isolation from the substrate 102; and the substrate 102 itself acting as the third well region to ensure enhanced isolation and reduced noise coupling.

In an embodiment, the recess channel transistor TRB includes a gate dielectric film 120 covering the inner wall of the recess trench 102R, a plurality of source/drain regions 116 arranged in the pocket well 112P, and a channel region CH arranged in the pocket well 112P to be adjacent to the bottom of the recess trench 102R. In the recess channel transistor TRB, the plurality of source/drain regions 116 may include a first source/drain region 116A arranged in a local region (which may be referred to as a first active region), which is surrounded by the recess trench 102R and the gate electrode 130 in a plan view, of the active region AC, and a second source/drain region 116B arranged in a local region (which may be referred to as a second active region), which is between the device isolation film 114 and both of the recess trench 102R and the gate electrode 130 in a plan view, of the active region AC. A more detailed configuration of the recess channel transistor TRB is substantially the same as that of the recess channel transistor TRA described with reference to FIGS. 1A and 1B.

When the recess channel transistor TRB includes an NMOS transistor, each of the deep well 106 and the plurality of source/drain regions 116 may include an impurity region doped with an N-type impurity, and the pocket well 112P may include an impurity region doped with a P-type impurity. When the recess channel transistor TRB includes a PMOS transistor, each of the deep well 106 and the plurality of source/drain regions 116 may include an impurity region doped with a P-type impurity, and the pocket well 112P may include an impurity region doped with an N-type impurity.

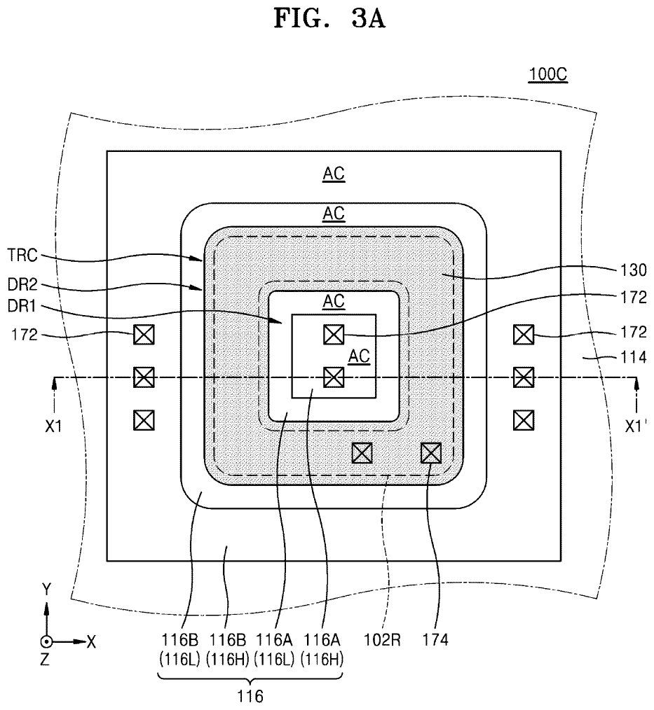

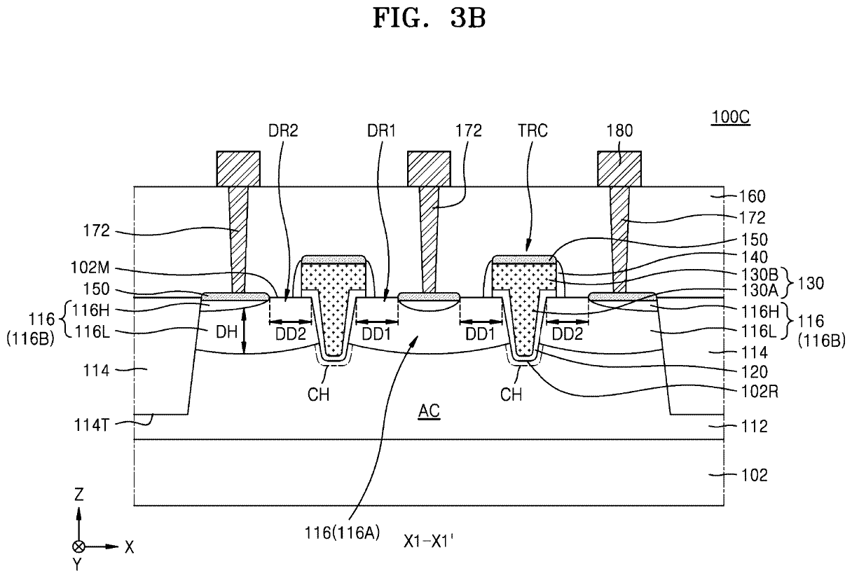

FIG. 3A is a planar layout diagram illustrating an integrated circuit device 100C according to some embodiments. FIG. 3B is a cross-sectional view of the integrated circuit device 100C, taken along a line X1-X1′ of FIG. 3A. In FIGS. 3A and 3B, the same reference numerals as in FIGS. 1A and 1B respectively denote the same members, and here, repeated descriptions thereof are omitted.

Referring to FIGS. 3A and 3B, the integrated circuit device 100C has substantially the same configuration as the integrated circuit device 100A shown in FIGS. 1A and 1B. However, the integrated circuit device 100C includes a recess channel transistor TRC. The recess channel transistor TRC has substantially the same configuration as the recess channel transistor TRA described with reference to FIGS. 1A and 1B. However, the lightly-doped region 116L of each of the first source/drain region 116A and the second source/drain region 116B of the recess channel transistor TRC includes a drift region extending in the horizontal direction (for example, the X direction or the Y direction) between the heavily-doped region 116H and the recess trench 102R. More specifically, the lightly-doped region 116L of the first source/drain region 116A of the recess channel transistor TRC includes a first drift region DR1 arranged between the heavily-doped region 116H of the first source/drain region 116A and the recess trench 102R and extending in the horizontal direction (for example, the X direction or the Y direction) from the heavily-doped region 116H toward the gate electrode 130. The lightly-doped region 116L of the second source/drain region 116B of the recess channel transistor TRC includes a second drift region DR2 arranged between the heavily-doped region 116H of the second source/drain region 116B and the recess trench 102R and extending in the horizontal direction (for example, the X direction or the Y direction) from the heavily-doped region 116H toward the gate electrode 130. The first drift region DR1 and the second drift region DR2 may be spaced apart from each other in the horizontal direction with the gate electrode 130 therebetween.

In a plan view, the first drift region DR1 may have a closed-loop shape surrounding the heavily-doped region 116H of the first source/drain region 116A. In a plan view, the second drift region DR2 may have a closed-loop shape surrounding the recess trench 102R, the gate electrode 130, and the first drift region DR1.

In the first source/drain region 116A, the heavily-doped region 116H may be spaced apart from the gate electrode 130 and the gate dielectric film 120 in the horizontal direction with the first drift region DR1 therebetween. In the second source/drain region 116B, the heavily-doped region 116H may be spaced apart from the gate electrode 130 and the gate dielectric film 120 in the horizontal direction with the second drift region DR2 therebetween. In some embodiments, in the horizontal direction (for example, the X direction or the Y direction), a first width DD1 of the first drift region DR1 and a second width DD2 of the second drift region DR2 may each be more than about 0 μm but not more than about 3 μm. For example, each of the first width DD1 of the first drift region DR1 and the second width DD2 of the second drift region DR2 may be selected from, but is not limited to, a range of about 0.1 μm to about 2 μm.

In some embodiments, the first width DD1 of the first drift region DR1 may be equal to the second width DD2 of the second drift region DR2. In this case, in a cross-sectional structure (for example, a cross-sectional structure taken along the X-Z plane) of the recess channel transistor TRC, the first source/drain region 116A and the second source/drain region 116B, which are respectively on both sides of the gate electrode 130 in the horizontal direction, may have symmetric structures to each other about the gate electrode 130.

In some embodiments, the first width DD1 of the first drift region DR1 may be different from the second width DD2 of the second drift region DR2. In this case, in the cross-sectional structure (for example, a cross-sectional structure taken along the X-Z plane) of the recess channel transistor TRC, the first source/drain region 116A and the second source/drain region 116B, which are respectively on both sides of the gate electrode 130 in the horizontal direction, may have asymmetric structures to each other about the gate electrode 130.

Each of the plurality of source/drain regions 116 of the recess channel transistor TRC of the integrated circuit device 100C shown in FIGS. 3A and 3B secures a sufficient vertical-direction (Z-direction) length DH of the lightly-doped region 116L and further includes the first drift region DR1 and the second drift region DR2, thereby further improving voltage-resistant characteristics of the recess channel transistor TRC even without forcibly increasing a channel length.

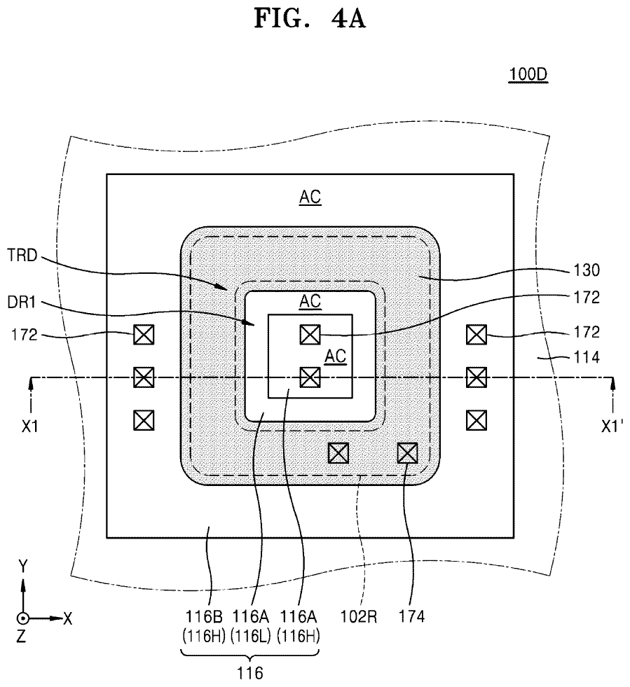

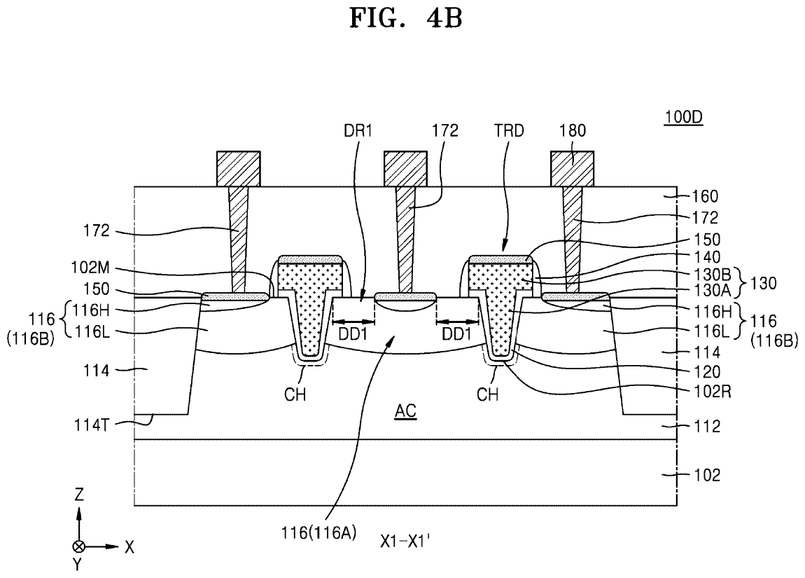

FIG. 4A is a planar layout diagram illustrating an integrated circuit device 100D according to some embodiments. FIG. 4B is a cross-sectional view of the integrated circuit device 100D, taken along a line X1-X1′ of FIG. 4A. In FIGS. 4A and 4B, the same reference numerals as in FIGS. 1A, 1B, 3A, and 3B respectively denote the same members, and here, repeated descriptions thereof are omitted.

Referring to FIGS. 4A and 4B, the integrated circuit device 100D has substantially the same configuration as the integrated circuit device 100A shown in FIGS. 1A and 1B. However, the integrated circuit device 100D includes a recess channel transistor TRD. The recess channel transistor TRD has substantially the same configuration as the recess channel transistor TRA described with reference to FIGS. 1A and 1B. However, the lightly-doped region 116L of the first source/drain region 116A of the recess channel transistor TRD includes a first drift region DR1 arranged between the heavily-doped region 116H and the recess trench 102R and extending in the horizontal direction (for example, the X direction or the Y direction) from the heavily-doped region 116H toward the gate electrode 130. The second source/drain region 116B may not include a drift region extending in the horizontal direction from the heavily-doped region 116H toward the gate electrode 130.

The first drift region DR1 of the first source/drain region 116A may extend in the horizontal direction (for example, the X direction or the Y direction) between the heavily-doped region 116H of the first source/drain region 116A and the recess trench 102R. A more detailed configuration of the first drift region DR1 of the first source/drain region 116A is the same as that described with reference to FIGS. 3A and 3B.

In a cross-sectional structure (for example, a cross-sectional structure taken along the X-Z plane) of the recess channel transistor TRD, because, out of the first source/drain region 116A and the second source/drain region 116B respectively on both sides of the gate electrode 130 in the horizontal direction, only the first source/drain region 116A includes the first drift region DR1 and the second source/drain region 116B includes no drift region, the first source/drain region 116A and the second source/drain region 116B, which are respectively on both sides of the gate electrode 130 in the horizontal direction, may have asymmetric structures to each other about the gate electrode 130.

In the integrated circuit device 100D shown in FIGS. 4A and 4B, because the first drift region DR1 is included in the lightly-doped region 116L in only the first source/drain region 116A, out of the first source/drain region 116A and the second source/drain region 116B of the recess channel transistor TRD, a structure having a good effect in reducing the size of the recess channel transistor TRD may be provided, and voltage-resistant characteristics of the recess channel transistor TRD may further improve even without forcibly increasing the channel length of the recess channel transistor TRD.

Although FIGS. 4A and 4B illustrate a configuration in which the first drift region DR1 is included in the lightly-doped region 116L in only the first source/drain region 116A out of the first source/drain region 116A and the second source/drain region 116B of the recess channel transistor TRD, the inventive concept is not limited thereto. For example, a configuration, in which no drift region is included in the first source drain region 116A out of the first source/drain region 116A and the second source/drain region 116B of the recess channel transistor TRD and the second drift region DR2 described with reference to FIGS. 3A and 3B is included in the lightly-doped region 116L in only the second source drain region 116B, may also fall within the scope of the inventive concept.

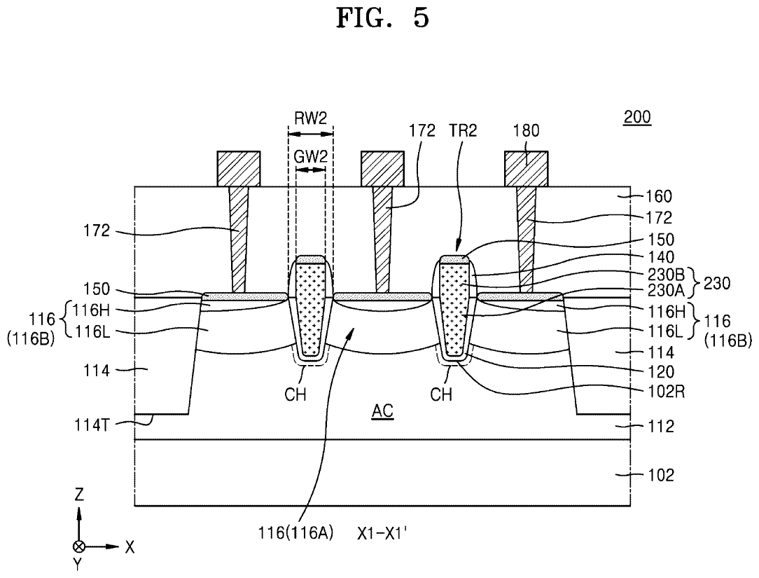

FIG. 5 is a cross-sectional view illustrating an integrated circuit device 200 according to an embodiment. FIG. 5 illustrates a cross-sectional configuration of a portion of the integrated circuit device 200, the portion corresponding to the cross-section taken along the line X1-X1′ of FIG. 1A. In FIG. 5, the same reference numerals as in FIGS. 1A and 1B respectively denote the same members, and here, repeated descriptions thereof are omitted.

Referring to FIG. 5, the integrated circuit device 200 has substantially the same configuration as the integrated circuit device 100A shown in FIGS. 1A and 1B. However, a recess channel transistor TR2 of the integrated circuit device 200 includes a gate electrode 230. Similar to the gate electrode 130 described with reference to FIGS. 1A and 1B, the gate electrode 230 may have a closed-loop shape in a plan view.

In an embodiment, the gate electrode 230 includes a buried electrode portion 230A, which is arranged on the gate dielectric film 120 to fill the recess trench 102R, and a protruding electrode portion 230B, which is integrally connected to the buried electrode portion 230A and protrudes above the main surface 102M of the substrate 102. In a plan view, each of the buried electrode portion 230A and the protruding electrode portion 230B of the gate electrode 230 may be apart from the device isolation film 114 in the horizontal direction with a sufficient distance therebetween not to overlap the device isolation film 114 in the vertical direction (the Z direction). For example, as shown in FIG. 5, in the first horizontal direction (the X direction), each of the buried electrode portion 230A and the protruding electrode portion 230B of the gate electrode 230 may be arranged to be sufficiently apart from the device isolation film 114 in the horizontal direction with the second source/drain region 116B therebetween, the second source/drain region 116B being one of the plurality of source/drain regions 116.

In a width direction of the gate electrode 230, according to an embodiment, a first width GW2 of the protruding electrode portion 230B of the gate electrode 230 is less than a second width RW2 of the recess trench 102R. A more detailed configuration of the gate electrode 230 is substantially similar to that of the gate electrode 130 described with reference to FIGS. 1A and 1B.

In the integrated circuit device 200, the protruding electrode portion 230B of the gate electrode 230 of the recess channel transistor TR2 may have a relatively small width, whereby the area occupied by the recess channel transistor TR2 in the integrated circuit device 200 may be further reduced.

For example, the primary difference between FIG. 5 and FIG. 1 is that FIG. 3 features a narrower gate electrode, making the transistor more compact and potentially increasing integration, whereas FIGS. 1A and 1B has a wider gate electrode, offering stronger gate control but occupying more space.

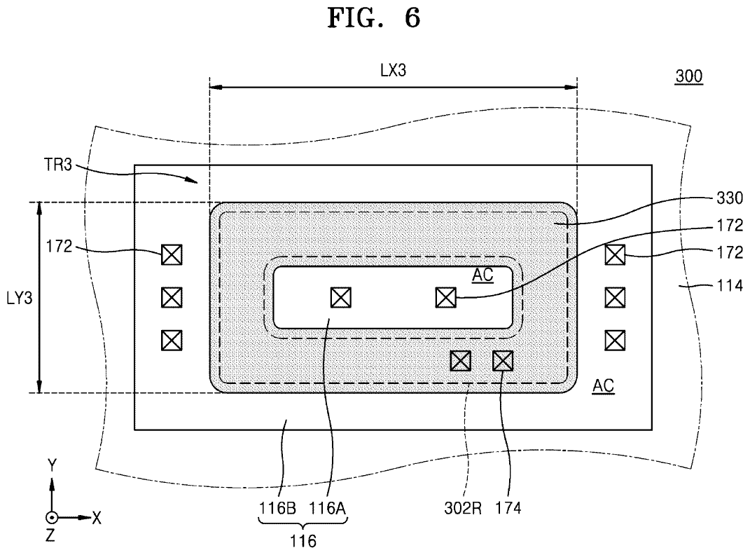

FIGS. 6, 7, and 8 are planar layout diagrams respectively illustrating integrated circuit devices 300, 400, and 500 according to some embodiments. In FIGS. 6, 7, and 8, the same reference numerals as in FIGS. 1A and 1B respectively denote the same members, and here, repeated descriptions thereof are omitted.

Referring to FIG. 6, the integrated circuit device 300 includes a recess channel transistor TR3. The recess channel transistor TR3 has substantially the same configuration as the recess channel transistor TRA described with reference to FIGS. 1A and 1B. However, the recess channel transistor TR3 of the integrated circuit device 300 includes a gate electrode 330. The gate electrode 330 of the recess channel transistor TR3, and a recess trench 302R accommodating a portion of the gate electrode 330 may each have a rectangular closed-loop shape with rounded corners, in a plan view. In a plan view, a first length LX3 of the gate electrode 330 in the first horizontal direction (the X direction) may be different from a second length LY3 of the gate electrode 330 in the second horizontal direction (the Y direction) that is orthogonal to the first horizontal direction (the X direction). FIG. 6 illustrates an example in which the first length LX3 of the gate electrode 330 in the first horizontal direction (the X direction) is greater than the second length LY3 of the gate electrode 330 in the second horizontal direction (the Y direction). However, the inventive concept is not limited to the example shown in FIG. 6. For example, the second length LY3 of the gate electrode 330 in the second horizontal direction (the Y direction) may be greater than the first length LX3 of the gate electrode 330 in the first horizontal direction (the X direction).

FIG. 6 differs from FIGS. 1A and 1B primarily in the plan-view shape of the gate electrode and recess trench. FIGS. 1A and 1B has a quadrangular (square-like) shape, while FIG. 6 features a rectangular shape elongated in one direction, which may be used to optimize the transistor's performance characteristics or adapt to layout constraints.

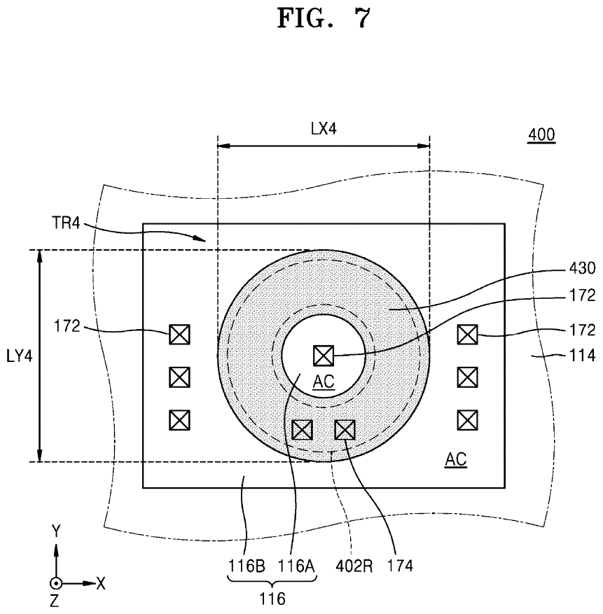

Referring to FIG. 7, the integrated circuit device 400 includes a recess channel transistor TR4. The recess channel transistor TR4 has substantially the same configuration as the recess channel transistor TRA described with reference to FIGS. 1A and 1B. However, the recess channel transistor TR4 of the integrated circuit device 400 includes a gate electrode 430. In an embodiment, the gate electrode 430 of the recess channel transistor TR4, and a recess trench 402R accommodating a portion of the gate electrode 430 each have a circular closed-loop shape in a plan view. In a plan view, a first length LX4 of the gate electrode 430 in the first horizontal direction (the X direction) may be equal to or substantially equal to a second length LY4 of the gate electrode 430 in the second horizontal direction (the Y direction) that is orthogonal to the first horizontal direction (the X direction).

FIG. 7 differs from FIGS. 1A and 1B primarily in the shape of the gate electrode and recess trench. While FIGS. 1A and 1B has a quadrangular shape, FIG. 7 features a circular closed-loop shape, which may help enhance threshold voltage stability and reduce electric field concentration at edges, enhancing transistor reliability.

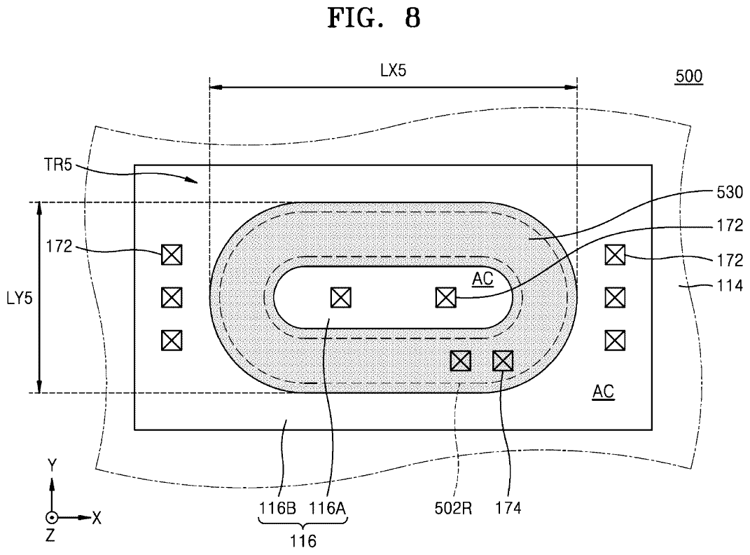

Referring to FIG. 8, the integrated circuit device 500 includes a recess channel transistor TR5. The recess channel transistor TR5 has substantially the same configuration as the recess channel transistor TRA described with reference to FIGS. 1A and 1B. However, the recess channel transistor TR5 of the integrated circuit device 500 includes a gate electrode 530. In an embodiment, the gate electrode 530 of the recess channel transistor TR5, and a recess trench 502R accommodating a portion of the gate electrode 530 each have an elliptical closed-loop shape in a plan view. In a plan view, a first length LX5 of the gate electrode 530 in the first horizontal direction (the X direction) may be different from a second length LY5 of the gate electrode 530 in the second horizontal direction (the Y direction) that is orthogonal to the first horizontal direction (the X direction). FIG. 8 illustrates an example in which the first length LX5 of the gate electrode 530 in the first horizontal direction (the X direction) is greater than the second length LY5 of the gate electrode 530 in the second horizontal direction (the Y direction). However, the inventive concept is not limited to the example shown in FIG. 8. For example, the second length LY5 of the gate electrode 530 in the second horizontal direction (the Y direction) may be greater than the first length LX5 of the gate electrode 530 in the first horizontal direction (the X direction).

FIG. 8 differs from FIGS. 1A and 1B primarily in the shape of the gate electrode and recess trench. While FIGS. 1A and 1B has a quadrangular shape, FIG. 8 features an elliptical closed-loop shape, which may provide benefits in terms of current directionality and electric field distribution, potentially enhancing certain performance characteristics of the transistor.

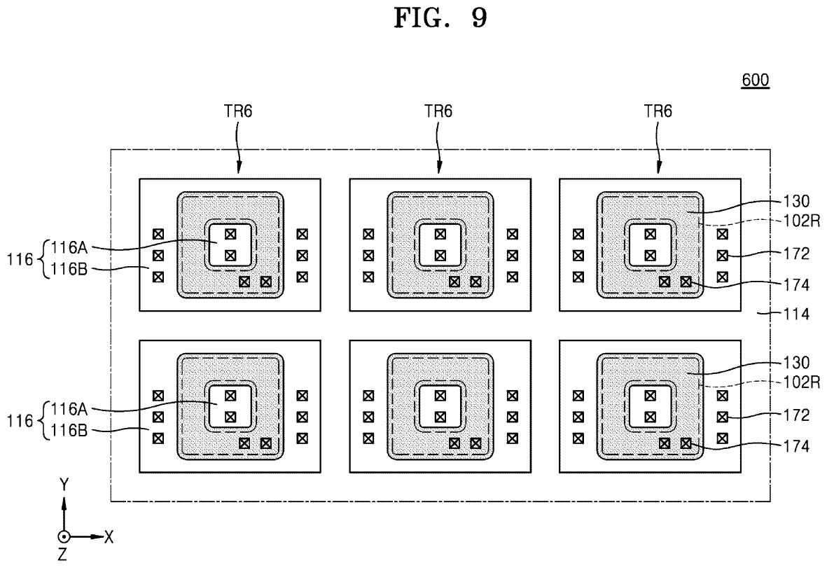

FIG. 9 is a planar layout diagram illustrating an integrated circuit device 600 according to an embodiment. In FIG. 9, the same reference numerals as in FIGS. 1A and 1B respectively denote the same members, and here, repeated descriptions thereof are omitted.

Referring to FIG. 9, the integrated circuit device 600 includes a plurality of recess channel transistors TR6. Each of the plurality of recess channel transistors TR6 may have substantially the same configuration as the recess channel transistor TRA described with reference to FIGS. 1A and 1B.

In the integrated circuit device 600, the plurality of recess channel transistors TR6 may be arranged apart from each other with the device isolation film 114 therebetween. At least some of the plurality of recess channel transistors TR6 may be connected to each other in series or in parallel.

Although FIG. 9 illustrates an example where a plurality of recess channel transistors TR6 are arranged in a matrix configuration, with three recess channel transistors TR6 aligned in a row along the first horizontal direction (the X direction) and two recess channel transistors TR6 aligned in a row along the second horizontal direction (the Y direction), the inventive concept is not limited thereto. In the plurality of recess channel transistors TR6, the respective numbers of recess channel transistors TR6 arranged in the first horizontal direction (the X direction) and the second horizontal direction (the Y direction), and the overall arrangement structure of the recess channel transistors TR6 may be variously modified as needed.

Although FIG. 9 illustrates an example in which each of the plurality of recess channel transistors TR6 of the integrated circuit device 600 has the same configuration as the recess channel transistor TRA described with reference to FIGS. 1A and 1B, the inventive concept is not limited thereto. For example, in the integrated circuit device 600, the recess channel transistor TRB, TRC, TRD, TR2, TR3, TR4, or TR5 shown in FIGS. 2 to 8, recess channel transistors having various structures changed and modified from the recess channel transistor TRB, TRC, TRD, TR2, TR3, TR4, or TR5 without departing from the scope of the inventive concept, or recess channel transistors including combinations thereof may be used instead of the plurality of recess channel transistors TR6.

According to some embodiments, each of the recess channel transistors TR2, TR3, TR4, TR5, and TR6 shown in FIGS. 5 to 9 may further include at least one of the first drift region DR1 in the first source/drain region 116A and the second drift region DR2 in the second source/drain region 116B, which are described with reference to FIGS. 3A and 3B.

FIG. 9 differs from FIGS. 1A and 1B primarily by featuring multiple recess channel transistors arranged in an array, whereas FIGS. 1A and 1B depicts a single transistor. This difference enables scalability, higher current handling, and integrated circuit flexibility, making FIG. 9 suitable for applications requiring multiple transistors working together in a structured layout.

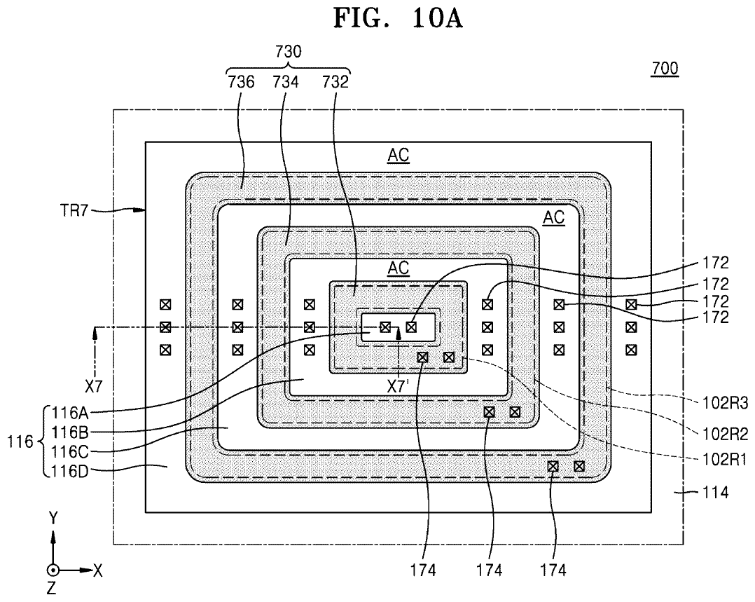

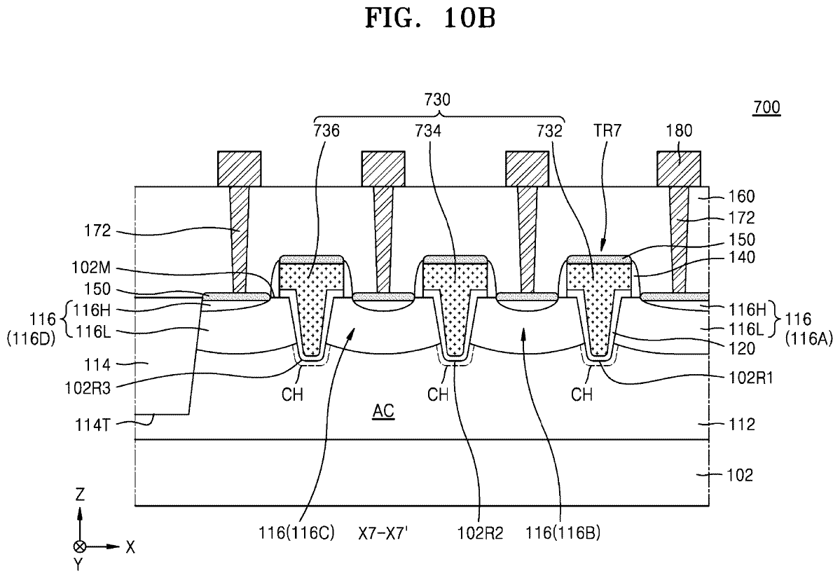

FIG. 10A is a planar layout diagram illustrating an integrated circuit device 700 according to an embodiment. FIG. 10B is a cross-sectional view of the integrated circuit device 700, taken along a line X7-X7′ of FIG. 10A. In FIGS. 10A and 10B, the same reference numerals as in FIGS. 1A and 1B respectively denote the same members, and here, repeated descriptions thereof are omitted.

Referring to FIGS. 10A and 10B, the integrated circuit device 700 includes a recess channel transistor TR7. The recess channel transistor TR7 may include components similar to those of the recess channel transistor TRA described with reference to FIGS. 1A and 1B. However, the recess channel transistor TR7 includes a plurality of recess trenches, a plurality of gate electrodes 730 respectively filling the plurality of recess trenches, and a plurality of source/drain regions 116. The plurality of recess trenches includes a first recess trench 102R1, a second recess trench 102R2, and a third recess trench 102R3. The plurality of gate electrodes 730 include a first gate electrode 732 filling the first recess trench 102R1, a second gate electrode 734 filling the second recess trench 102R2, and a third gate electrode 736 filling the third recess trench 102R3. Herein, each of the second recess trench 102R2 and the third recess trench 102R3 may be referred to as an outer recess trench. Herein, each of the second gate electrode 734 and the third gate electrode 736 may be referred to as an outer gate electrode.

The plurality of source/drain regions 116 include first to fourth source/drain regions 116A, 116B, 116C, and 116D. In a plan view, the first source/drain region 116A may be arranged in a local region (which may be referred to as a first active region) surrounded by the first recess trench 102R1 and may be surrounded by the first gate electrode 732. In a plan view, the second source/drain region 116B may be arranged in a local region (which may be referred to as a second active region) between the first recess trench 102R1 and the second recess trench 10 2R2. The second source/drain region 116B may be arranged between the first gate electrode 732 and the second gate electrode 734 and may be surrounded by the second gate electrode 734. In a plan view, the third source/drain region 116C may be arranged in a local region (which may be referred to as a third active region) between the second recess trench 102R2 and the third recess trench 102R3. The third source/drain region 116C may be arranged between the second gate electrode 734 and the third gate electrode 736 and may be surrounded by the third gate electrode 736. In a plan view, the fourth source/drain region 116D may be arranged in a local region (which may be referred to as a fourth active region) between the third recess trench 102R3 and the device isolation film 114. The fourth source/drain region 116D may be arranged between the third gate electrode 736 and the device isolation film 114 and may be surrounded by the device isolation film 114.

An upper surface of each of the plurality of source/drain regions 116 and the plurality of gate electrodes 730 may be covered by a metal silicide film 150. Each of the plurality of source/drain regions 116 may be connected to at least one source/drain contact plug 172 via the metal silicide film 150. Each of the plurality of gate electrodes 730 may be connected to at least one gate contact plug 174 via the metal silicide film 150.

The first recess trench 102R1 is located apart from the device isolation film 114 and extends in the vertical direction (the Z direction) from the main surface 102M of the substrate 102 toward the inside of the substrate 102. The second recess trench 102R2 is arranged in the active region AC between the device isolation film 114 and the first recess trench 102R1 to be apart from the device isolation film 114 and extends in the vertical direction (the Z direction) from the main surface 102M of the substrate 102 toward the inside of the substrate 102. The third recess trench 102R3 is arranged in the active region AC between the device isolation film 114 and the second recess trench 102R2 to be apart from the device isolation film 114 and extends in the vertical direction (the Z direction) from the main surface 102M of the substrate 102 toward the inside of the substrate 102.

In the integrated circuit device 700, the plurality of recess trenches including the first recess trench 102R1, the second recess trench 102R2, and the third recess trench 102R3, and the plurality of gate electrodes 730 including the first to third gate electrodes 732, 734, and 736 each have a quadrangular closed-loop shape with rounded corners, in a plan view. In a plan view, the second recess trench 102R2 may be arranged apart from the first recess trench 102R1 and may surround the first recess trench 102R1, and the third recess trench 102R3 may be arranged apart from the second recess trench 102R2 and may surround the first recess trench 102R1 and the second recess trench 102R2. In a plan view, the second gate electrode 734 may surround the first gate electrode 732, and the third gate electrode 736 may surround the first gate electrode 732 and the second gate electrode 734.

In a plan view, the second to fourth source/drain regions 116B, 116C, and 116D from among the first to fourth source/drain regions 116A, 116B, 116C, and 116D of the plurality of source/drain regions 116 each have a closed-loop shape. The third gate electrode 736 closest to the device isolation film 114 and located at the outermost position, among the plurality of gate electrodes 730 in the recess channel transistor TR7, may be arranged to be sufficiently apart from the device isolation film 114 in the horizontal direction with the fourth source/drain region 116D therebetween, the fourth source/drain region 116D being closest to the device isolation film 114 among the plurality of source/drain regions 116 in the recess channel transistor TR7.

A more detailed configuration of each of the first recess trench 102R1, the second recess trench 102R2, and the third recess trench 102R3, which constitute the recess channel transistor TR7, is substantially the same as that of the recess trench 102R described with reference to FIGS. 1A and 1B. A more detailed configuration of each of the plurality of gate electrodes 730 in the recess channel transistor TR7 is substantially the same as that of the gate electrode 130 described with reference to FIGS. 1A and 1B. A more detailed configuration of each of the first to fourth source/drain regions 116A, 116B, 116C, and 116D in the recess channel transistor TR7 is substantially the same as that of the source/drain region 116 described with reference to FIGS. 1A and 1B. In some embodiments, in the recess channel transistor TR7 shown in FIGS. 10A and 10B, the third recess trench 102R3, the third gate electrode 736, and the fourth source/drain region 116D may be omitted.

FIGS. 10A and 10B differ from FIGS. 1A and 1B by featuring a recess trench with a variable depth, whereas FIGS. 1A and 1B uses a fixed-depth trench. This design modification may help optimize electric field characteristics, threshold voltage stability, and carrier mobility, making the structure of FIGS. 10A and 10B potentially more efficient for certain high-performance applications.

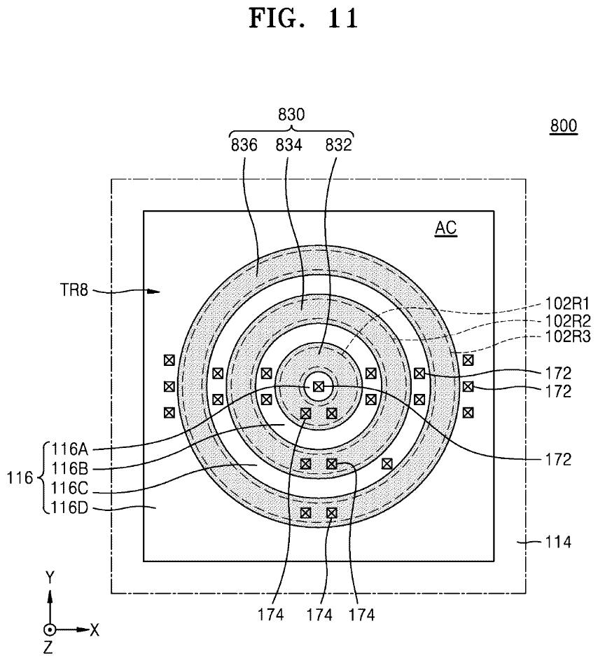

FIG. 11 is a planar layout diagram illustrating an integrated circuit device 800 according to an embodiment. In FIG. 11, the same reference numerals as in FIGS. 1A, 1B, 10A, and 10B respectively denote the same members, and here, repeated descriptions thereof are omitted.

Referring to FIG. 11, the integrated circuit device 800 includes a recess channel transistor TR8. The recess channel transistor TR8 may include components similar to those of the recess channel transistor TR7 described with reference to FIGS. 10A and 10B. However, the recess channel transistor TR8 includes a plurality of recess trenches including a first recess trench 102R1, a second recess trench 102R2, and a third recess trench 102R3, and a plurality of gate electrodes 830 respectively filling the plurality of recess trenches. The plurality of gate electrodes 830 include a first gate electrode 832 filling the first recess trench 102R1, a second gate electrode 834 filling the second recess trench 102R2, and a third gate electrode 836 filling the third recess trench 102R3. Herein, each of the second gate electrode 834 and the third gate electrode 836 may be referred to as an outer gate electrode.

The first source/drain region 116A may be surrounded by the first gate electrode 832. The second source/drain region 116B may be arranged between the first gate electrode 832 and the second gate electrode 834 and may be surrounded by the second gate electrode 834. The third source/drain region 116C may be arranged between the second gate electrode 834 and the third gate electrode 836 and may be surrounded by the third gate electrode 836. The fourth source/drain region 116D may be arranged between the third gate electrode 836 and the device isolation film 114 and may be surrounded by the device isolation film 114.

In the integrated circuit device 800, the plurality of recess trenches including the first recess trench 102R1, the second recess trench 10 2R2, and the third recess trench 102R3, and the plurality of gate electrodes 830 including the first to third gate electrodes 832, 834, and 836 each have a circular closed-loop shape. In a plan view, the second gate electrode 834 may surround the first gate electrode 832, and the third gate electrode 836 may surround the first gate electrode 832 and the second gate electrode 834.

The third gate electrode 836 closest to the device isolation film 114 and located at the outermost position, among the plurality of gate electrodes 830 in the recess channel transistor TR8, may be arranged to be sufficiently apart from the device isolation film 114 in the horizontal direction with the fourth source/drain region 116D therebetween, the fourth source/drain region 116D being closest to the device isolation film 114 among the plurality of source/drain regions 116 in the recess channel transistor TR8.

A more detailed configuration of each of the plurality of gate electrodes 830 in the recess channel transistor TR8 is substantially the same as that of the gate electrode 130 described with reference to FIGS. 1A and 1B. In some embodiments, in the recess channel transistor TR8, the third recess trench 102R3, the third gate electrode 836, and the fourth source/drain region 116D may be omitted.

FIG. 11 differs from FIGS. 10A and 10B in that it features a stepped-depth recess trench, whereas FIGS. 10A and 10B has a variable-depth trench. The stepped-depth trench in FIG. 11 allows for precise electric field and charge control at different depths, which may be useful for reducing leakage current, enhancing carrier mobility, and fine-tuning transistor performance.

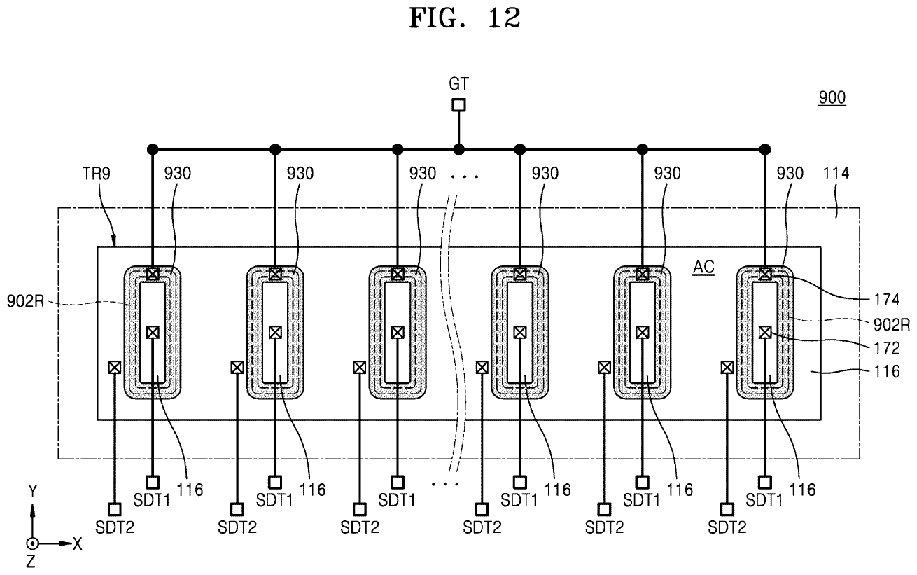

FIG. 12 is a planar layout diagram illustrating an integrated circuit device 900 according to an embodiment. In FIG. 12, the same reference numerals as in FIGS. 1A and 1B respectively denote the same members, and here, repeated descriptions thereof are omitted.

Referring to FIG. 12, the integrated circuit device 900 includes a recess channel transistor TR9. The recess channel transistor TR9 may include components similar to those of the recess channel transistor TRA described with reference to FIGS. 1A and 1B.

More specifically, the recess channel transistor TR9 includes a plurality of recess trenches 902R arranged in one active region AC, a plurality of gate electrodes 930 arranged on the one active region AC to respectively fill the plurality of recess trenches 902R, and a plurality of source/drain regions 116. The recess channel transistor TR9 may include an NMOS transistor or a PMOS transistor.

Each of the plurality of recess trenches 902R may have substantially the same configuration as the recess trench 102R described with reference to FIGS. 1A and 1B. Each of the plurality of gate electrodes 930 may have substantially the same configuration as the gate electrode 130 described with reference to FIGS. 1A and 1B.

As described with reference to FIG. 1B, each of the plurality of source/drain regions 116 may include a lightly-doped region 116L and a heavily-doped region 116H. In a plan view, the outermost source/drain region 116 closest to the device isolation film 114, among the plurality of source/drain regions 116, may surround all the plurality of gate electrodes 930 arranged on one active region AC. Other source/drain regions 116 except for the outermost source/drain region 116 among the plurality of source/drain regions 116 may each be surrounded by each one recess trench 902R and each one gate electrode 930.

The plurality of recess trenches 902R and the plurality of gate electrodes 930 each have a closed-loop shape in a plan view. Although FIG. 12 illustrates an example in which each of the plurality of recess trenches 902R and the plurality of gate electrodes 930 has a quadrangular closed-loop shape with rounded corners, the inventive concept is not limited thereto. For example, each of the plurality of recess trenches 902R and the plurality of gate electrodes 930 may have an elliptical or circular closed-loop shape in a plan view.

Similar to the gate electrode 130 described with reference to FIGS. 1A and 1B, a portion of each of the plurality of gate electrodes 930 may be accommodated in the recess trench 902R. The plurality of recess trenches 902R may be arranged apart from each other in one active region AC, and thus, the plurality of gate electrodes 930 may also be arranged apart from each other in the one active region AC.

In a plan view, each of the plurality of gate electrodes 930 may be arranged to be sufficiently apart from the device isolation film 114 in the horizontal direction (for example, the X direction and the Y direction). Each of the plurality of gate electrodes 930 may be arranged to be sufficiently apart from the device isolation film 114 in the horizontal direction with the outermost source/drain region 116 from among the plurality of source/drain regions 116 therebetween.

The plurality of gate contact plugs 174 respectively connected to the plurality of gate electrodes 930 may be connected to each other via a common gate terminal GT, and the plurality of gate electrodes 930 may be connected to each other in parallel. Source/drain regions 116 respectively surrounded by the plurality of gate electrodes 930, among the plurality of source/drain regions 116, may each be connected to a first source/drain terminal SDT1 via a source/drain contact plug 172, and the outermost source/drain region 116 surrounding the plurality of gate electrodes 930, among the plurality of source/drain regions 116, may be connected to a second source/drain terminal SDT2 via the source/drain contact plug 172.

The recess channel transistor TR9 in the integrated circuit device 900 may constitute a multi-finger transistor. In the recess channel transistor TR9, a channel width may be determined to be a value obtained by multiplying the number of gate electrodes 930 by a channel width obtained from one gate electrode 930. Therefore, the transconductance in the recess channel transistor TR9 may be increased, thereby enhancing the performance of the recess channel transistor TR9.

Similar to the integrated circuit device 100A described with reference to FIGS. 1A and 1B, according to the integrated circuit devices 100B, 100C, 100D, 200, 300, 400, 500, 600, 700, 800, and 900 described with reference to FIGS. 2 to 12, an off-current may be reduced by an increase in a channel length of a recess channel transistor, and a voltage-resistant effect of the recess channel transistor may be maximized. In addition, a gate electrode of each of recess channel transistors, which are included in the integrated circuit devices 100B, 100C, 100D, 200, 300, 400, 500, 600, 700, 800, and 900, is arranged in an active region to be sufficiently apart from a device isolation film with a source/drain region therebetween and has a closed-loop shape in a plan view. Therefore, an occupied area of a high-voltage transistor including the recess channel transistor may be reduced, and a hump phenomenon due to the formation of an unintended edge channel in the recess channel transistor may be prevented. In addition, the recess channel transistor in each of the integrated circuit devices 100B, 100C, 100D, 200, 300, 400, 500, 600, 700, 800, and 900 may be structured to effectively reduce threshold voltage variations among transistors in a chip while increasing its effective gate length. Therefore, each of the integrated circuit devices 100B, 100C, 100D, 200, 300, 400, 500, 600, 700, 800, and 900 according to the inventive concept may achieve intended performance with a minimum area in a reduced area and may provide excellent reliability.

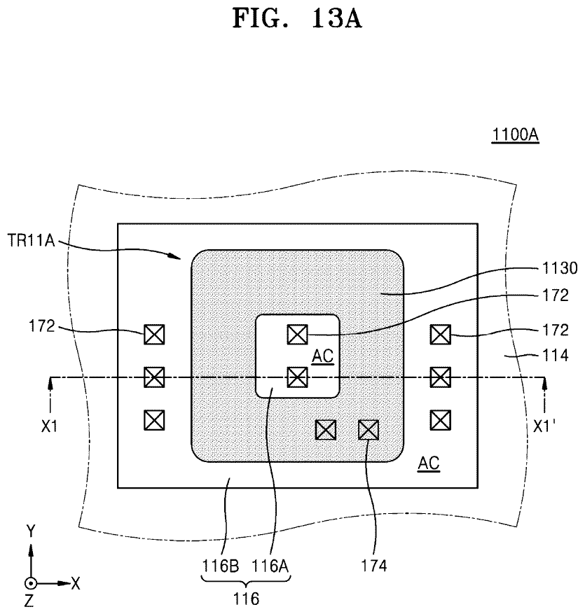

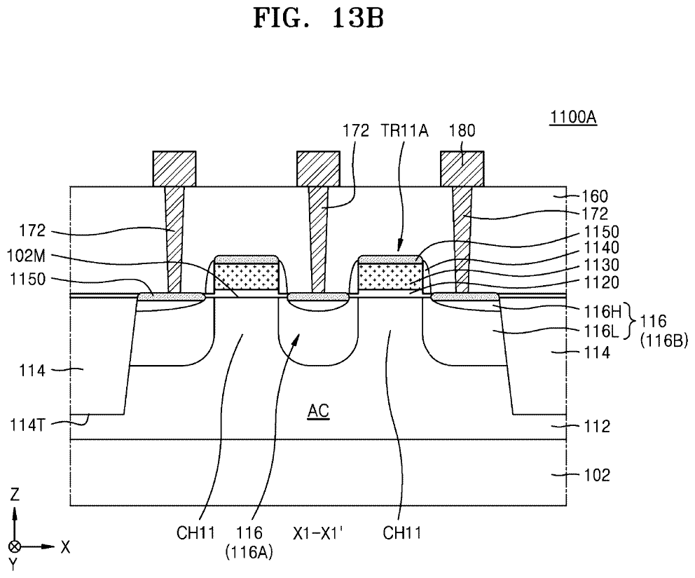

FIG. 13A is a planar layout diagram illustrating an integrated circuit device 1100A according to some embodiments. FIG. 13B is a cross-sectional view of the integrated circuit device 1100A, taken along a line X1-X1′ of FIG. 13A. In FIGS. 13A and 13B, the same reference numerals as in FIGS. 1A and 1B respectively denote the same members, and here, repeated descriptions thereof are omitted.

Referring to FIGS. 13A and 13B, the integrated circuit device 1100A has substantially the same configuration as the integrated circuit device 100A shown in FIGS. 1A and 1B. However, the integrated circuit device 1100A includes a planar transistor TR11A in which a gate and a channel meet each other at one surface. The planar transistor TR11A may be a transistor operated by any power supply voltage selected from a range of about 0.5 V to about 200 V.

The integrated circuit device 1100A includes a plurality of source/drain regions 116, which are arranged in the active region AC of the substrate 102, and a gate electrode 1130 arranged over the active region AC so as to be spaced apart from the device isolation film 114 in the horizontal direction (for example, the X direction or the Y direction). The gate electrode 1130 may be arranged apart from the main surface 102M of the substrate 102 in the vertical direction (the Z direction) with a gate dielectric film 1120 therebetween.

In a plan view, the gate electrode 1130 may have a closed-loop shape. The plurality of source/drain regions 116 may include a first source/drain region 116A and a second source/drain region 116B, which are spaced apart from each other with the gate electrode 1130 therebetween. In a plan view, the first source/drain region 116A may be surrounded by the gate electrode 1130. In a plan view, the second source/drain region 116B may be arranged between the device isolation film 114 and the gate electrode 1130, and the gate electrode 1130 and the first source/drain region 116A may be surrounded by the second source/drain region 116B. More detailed configurations of the first source/drain region 116A and the second source/drain region 116B are the same as those described with reference to FIGS. 1A and 1B.

In the active region AC of the substrate 102, a channel region CH11 may be arranged between the first source/drain region 116A and the second source/drain region 116B. In a plan view, the channel region CH11 may have a closed-loop shape extending along a region between the first source/drain region 116A and the second source/drain region 116B.

The gate dielectric film 1120 may include a first portion, which is arranged between the active region AC and the gate electrode 1130, and a second portion, which is arranged around the gate electrode 1130 and covers the substrate 102 and the device isolation film 114. In the gate dielectric film 1120, the thickness of the first portion may be greater than the thickness of the second portion. The first portion of the gate dielectric film 1120 may be arranged between the channel region CH11 of the active region AC and the gate electrode 1130. In some embodiments, in the gate dielectric film 1120, the thickness of the first portion may be equal to the thickness of the second portion. In some embodiments, the gate dielectric film 1120 may include only the first portion arranged between the active region AC and the gate electrode 1130. The gate dielectric film 1120 may include, but is not limited to, a silicon oxide film.

The integrated circuit device 1100A may include an insulating spacer 1140 covering sidewalls of the gate electrode 1130. The insulating spacer 1140 may include a portion vertically overlapping the plurality of source/drain regions 116. In some embodiments, the insulating spacer 1140 may include a silicon oxide film, a silicon nitride film, or a combination thereof.

As shown in FIG. 13A, the gate electrode 1130 may have a quadrangular closed-loop shape with rounded corners, in a plan view. For example, the gate electrode 1130 may have a square closed-loop shape with rounded corners. In some embodiments, the gate electrode 1130 may have a circular or elliptical shape in a plan view. In a plan view, the gate electrode 1130 may be spaced apart from the device isolation film 114 in the horizontal direction (the X direction and the Y direction) by as much as a sufficient distance such that the gate electrode 1130 does not overlap the device isolation film 114 in the vertical direction (the Z direction).

As shown in FIGS. 13A and 13B, in the horizontal direction (the X direction and the Y direction), the gate electrode 1130 may be arranged to be sufficiently apart from the device isolation film 114 with the second source/drain region 116B therebetween, the second source/drain region 116B being one of the plurality of source/drain regions 116.

An upper surface of the gate electrode 1130 and upper surfaces of the plurality of source/drain regions 116 may each be covered by a metal silicide film 1150. A more detailed configuration of the metal silicide film 1150 is substantially the same as that of the metal silicide film 150 described with reference to FIGS. 1A and 1B.

The device isolation film 114 and the planar transistor TR11A on the substrate 102 may be covered by an interlayer dielectric 160. The plurality of source/drain contact plugs 172 may each be connected to the metal silicide film 1150 through the interlayer dielectric 160 and may each be connected to the heavily-doped region 116H of each of the plurality of source/drain regions 116 via the metal silicide film 1150. The plurality of gate contact plugs 174 may each be connected to the metal silicide film 1150 through the interlayer dielectric 160 and may each be connected to the gate electrode 1130 via the metal silicide film 1150. The plurality of wiring layers 180 may be arranged on the interlayer dielectric 160. More detailed configurations of the interlayer dielectric 160, the plurality of source/drain contact plugs 172, the plurality of gate contact plugs 174, and the plurality of wiring layers 180 are the same as those described with reference to FIGS. 1A and 1B.

In the integrated circuit device 1100A described with reference to FIGS. 13A and 13B, the planar transistor TR11A includes the gate electrode 1130 arranged to be sufficiently apart from the device isolation film 114 with the second source/drain region 116B therebetween, the second source/drain region 116B being one of the plurality of source/drain regions 116 in the active region AC, and the gate electrode 1130 has a closed-loop shape in a plan view. Therefore, according to the integrated circuit device 1100A, the area occupied by the planar transistor TR11A on the substrate 102 may be reduced, and a structure having a good effect in down-scaling of the integrated circuit device 1100A may be provided. Therefore, according to the integrated circuit device 1100A, the planar transistor TR11A capable of achieving intended performance with a minimum area in a highly reduced area may be provided.

In addition, according to the integrated circuit device 1100A, a boundary region between the active region AC and the device isolation film 114 may not be affected by a voltage applied to the gate electrode 1130. Therefore, when a voltage lower than a threshold voltage is applied to the gate electrode 1130, issues, in which an unintended edge channel is formed in the vicinity of the interface between the active region AC and the device isolation film 114 or a hump phenomenon occurs due to the edge channel, may be prevented.

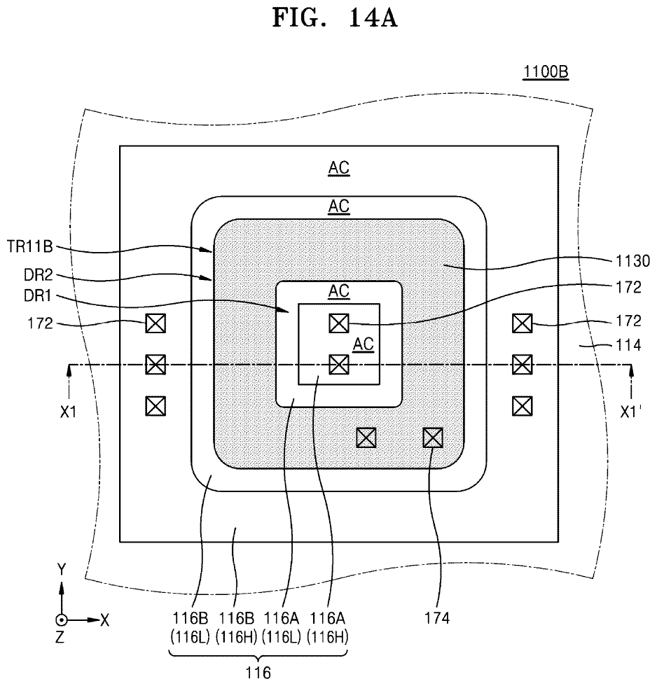

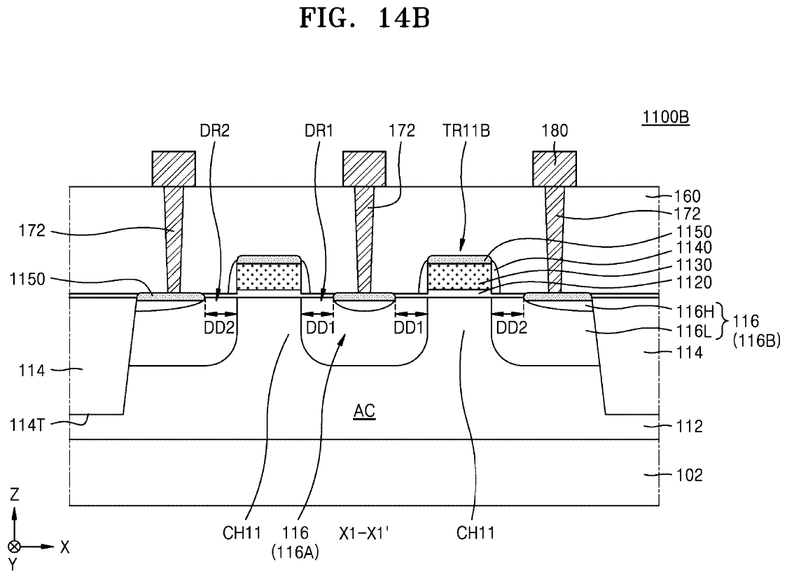

FIG. 14A is a planar layout diagram illustrating an integrated circuit device 1100B according to some embodiments. FIG. 14B is a cross-sectional view of the integrated circuit device 1100B, taken along a line X1-X1′ of FIG. 14A. In FIGS. 14A and 14B, the same reference numerals as in FIGS. 1A, 1B, 13A, and 13B respectively denote the same members, and here, repeated descriptions thereof are omitted.

Referring to FIGS. 14A and 14B, the integrated circuit device 1100B has substantially the same configuration as the integrated circuit device 1100A shown in FIGS. 13A and 13B. However, the integrated circuit device 1100B includes a planar transistor TR11B. The planar transistor TR11B has substantially the same configuration as the planar transistor TR11A described with reference to FIGS. 13A and 13B. However, the lightly-doped region 116L of each of the first source/drain region 116A and the second source/drain region 116B of the planar transistor TR11B includes a drift region extending in the horizontal direction (for example, the X direction or the Y direction) between the heavily-doped region 116H and the channel region CH11. More specifically, the lightly-doped region 116L of the first source/drain region 116A of the planar transistor TR11B includes a first drift region DR1 arranged between the heavily-doped region 116H of the first source/drain region 116A and the channel region CH11 and extending in the horizontal direction (for example, the X direction or the Y direction) from the heavily-doped region 116H toward the gate electrode 1130 and the channel region CH11. The lightly-doped region 116L of the second source/drain region 116B of the planar transistor TR11B includes a second drift region DR2 arranged between the heavily-doped region 116H of the second source/drain region 116B and the channel region CH11 and extending in the horizontal direction (for example, the X direction or the Y direction) from the heavily-doped region 116H toward the gate electrode 1130 and the channel region CH11. The first drift region DR1 and the second drift region DR2 may be spaced apart from each other in the horizontal direction with the channel region CH11 therebetween.

In a plan view, the first drift region DR1 may have a closed-loop shape surrounding the heavily-doped region 116H of the first source/drain region 116A. In a plan view, the second drift region DR2 may have a closed-loop shape surrounding the gate electrode 1130 and the first drift region DR1.

In the first source/drain region 116A, the heavily-doped region 116H may be spaced apart from the channel region CH11 in the horizontal direction with the first drift region DR1 therebetween. In the second source/drain region 116B, the heavily-doped region 116H may be spaced apart from the channel region CH11 in the horizontal direction with the second drift region DR2 therebetween. In some embodiments, in the horizontal direction (for example, the X direction or the Y direction), the first width DD1 of the first drift region DR1 and the second width DD2 of the second drift region DR2 may each be more than about 0 μm but not more than about 3 μm. For example, each of the first width DD1 of the first drift region DR1 and the second width DD2 of the second drift region DR2 may be selected from, but is not limited to, a range of about 0.1 μm to about 2 μm. More detailed configurations of the first width DD1 and the second width DD2 are the same as those described with reference to FIGS. 3A and 3B.

In some embodiments, when the first width DD1 of the first drift region DR1 is equal to the second width DD2 of the second drift region DR2, the first source/drain region 116A and the second source/drain region 116B, which are respectively on both sides of the channel region CH11 in the horizontal direction, in a cross-sectional structure (for example, a cross-sectional structure taken along the X-Z plane) of the planar transistor TR11B, may have symmetric structures to each other about the channel region CH11.

In some embodiments, when the first width DD1 of the first drift region DR1 is different from the second width DD2 of the second drift region DR2, the first source/drain region 116A and the second source/drain region 116B, which are respectively on both sides of the channel region CH11 in the horizontal direction, in a cross-sectional structure (for example, a cross-sectional structure taken along the X-Z plane) of the planar transistor TR11B, may have asymmetric structures to each other about the channel region CH11.

According to the integrated circuit device 1100B shown in FIGS. 14A and 14B, the plurality of source/drain regions 116 of the planar transistor TR11B may include the first drift region DR1 and the second drift region DR2, thereby further improving voltage-resistant characteristics of the planar transistor TR11B.

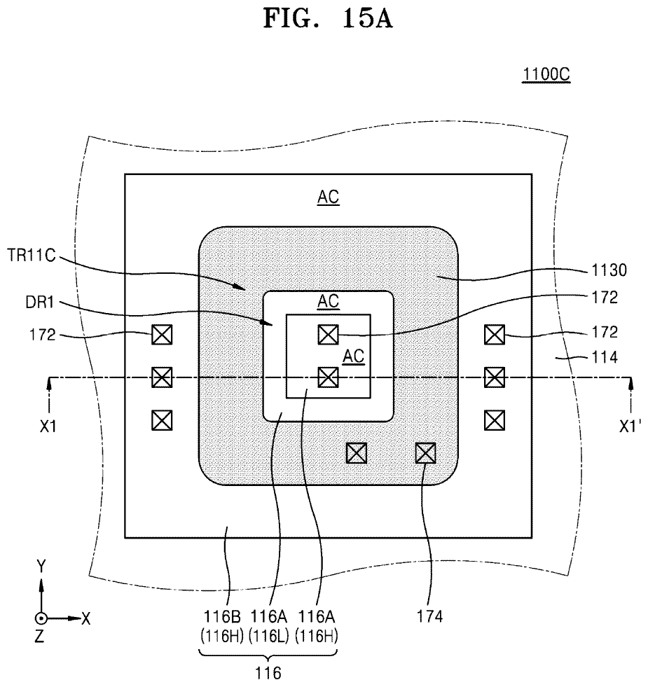

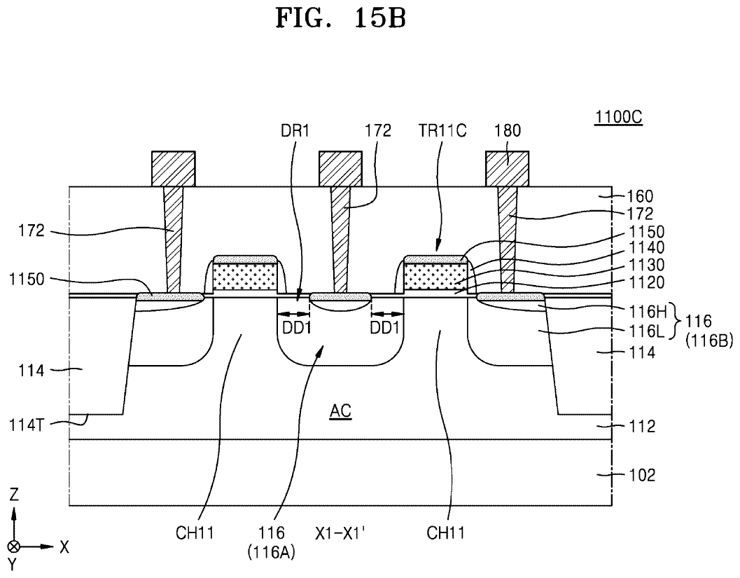

FIG. 15A is a planar layout diagram illustrating an integrated circuit device 1100C according to some embodiments. FIG. 15B is a cross-sectional view of the integrated circuit device 1100C, taken along a line X1-X1′ of FIG. 15A. In FIGS. 15A and 15B, the same reference numerals as in FIGS. 1A, 1B, 13A, 13B, 14A, and 14B respectively denote the same members, and here, repeated descriptions thereof are omitted.

Referring to FIGS. 15A and 15B, the integrated circuit device 1100C has substantially the same configuration as the integrated circuit device 1100A shown in FIGS. 13A and 13B. However, the integrated circuit device 1100C includes a planar transistor TR11C. The planar transistor TR11C has substantially the same configuration as the planar transistor TR11A described with reference to FIGS. 13A and 13B. However, the lightly-doped region 116L of the first source/drain region 116A of the planar transistor TR11C includes a first drift region DR1 arranged between the heavily-doped region 116H and the channel region CH11 and extending in the horizontal direction (for example, the X direction or the Y direction) from the heavily-doped region 116H toward the gate electrode 1130 and the channel region CH11. The second source/drain region 116B may not include a drift region extending in the horizontal direction from the heavily-doped region 116H toward the gate electrode 1130 and the channel region CH11.

The first drift region DR1 of the first source/drain region 116A may extend in the horizontal direction (for example, the X direction or the Y direction) between the heavily-doped region 116H of the first source/drain region 116A and the channel region CH11. A more detailed configuration of the first drift region DR1 of the first source/drain region 116A is the same as that described with reference to FIGS. 3A and 3B.

In a cross-sectional structure (for example, a cross-sectional structure taken along the X-Z plane) of the planar transistor TR11C, because the first drift region DR1 is included in only the first source/drain region 116A out of the first source/drain region 116A and the second source/drain region 116B, which are respectively on both sides of the gate electrode 1130 in the horizontal direction, and there is no drift region in the second source/drain region 116B, the first source/drain region 116A and the second source/drain region 116B, which are respectively on both sides of the channel region CH11 in the horizontal direction, may have asymmetric structures to each other about the channel region CH11.

In the integrated circuit device 1100C shown in FIGS. 15A and 15B, because only the first source/drain region 116A out of the first source/drain region 116A and the second source/drain region 116B of the planar transistor TR11C includes the first drift region DR1 in the lightly-doped region 116L, a structure having a good effect in reducing the size of the planar transistor TR11C may be provided, and voltage-resistant characteristics of the planar transistor TR11C may further improve.

Although FIGS. 15A and 15B illustrate a configuration in which the first drift region DR1 is included in the lightly-doped region 116L in only the first source/drain region 116A out of the first source/drain region 116A and the second source/drain region 116B of the planar transistor TR11C, the inventive concept is not limited thereto. For example, a configuration, in which no drift region is included in the first source drain region 116A out of the first source/drain region 116A and the second source/drain region 116B of the planar transistor TR11C and the second drift region DR2 described with reference to FIGS. 3A and 3B is included in the lightly-doped region 116L in only the second source drain region 116B, may also fall within the scope of the inventive concept.

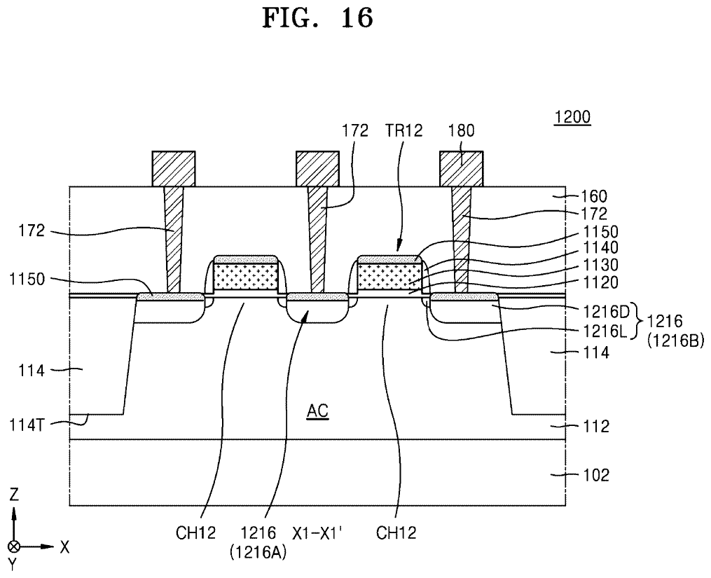

FIG. 16 is a cross-sectional view illustrating an integrated circuit device 1200 according to some embodiments. FIG. 16 illustrates a cross-sectional configuration of a portion of the integrated circuit device 1200, the portion corresponding to a cross-section taken along the line X1-X1′ of FIG. 13A. In FIG. 16, the same reference numerals as in FIGS. 13A and 13B respectively denote the same members, and here, repeated descriptions thereof are omitted.

Referring to FIG. 16, the integrated circuit device 1200 has substantially the same configuration as the integrated circuit device 1100A shown in FIGS. 13A and 13B. However, the integrated circuit device 1200 includes a planar transistor TR12. The planar transistor TR12 has substantially the same configuration as the planar transistor TR11A described with reference to FIGS. 13A and 13B. However, a plurality of source/drain regions 1216 of the planar transistor TR12 each have a lightly doped drain (LDD) structure. In some embodiments, the planar transistor TR12 may be a low-voltage transistor operated by a relatively low power supply voltage of about 0.7 V to about 3.3 V.

The plurality of source/drain regions 1216 may include a first source/drain region 1216A and a second source/drain region 1216B that are spaced apart from each other with a channel region CH12 therebetween. In a plan view, the first source/drain region 1216A may be surrounded by a gate electrode 1130. In a plan view, the second source/drain region 1216B may be arranged between the device isolation film 114 and the gate electrode 1130, and the gate electrode 1130 and the first source/drain region 1216A may be surrounded by the second source/drain region 1216B. Each of the first source/drain region 1216A and the second source/drain region 1216B may include a shallow source/drain region 1216L and a deep source/drain region 1216D.

In the integrated circuit devices 1100B, 1100C, and 1200 described with reference to FIGS. 14A to 16, each of the planar transistors TR11B, TR11C, and TR12 includes the gate electrode 1130 arranged to be sufficiently apart from the device isolation film 114 with the second source/drain region 116B or 1216B therebetween, the second source/drain region 116B or 1216B being one of the plurality of source/drain regions 116 or one of the plurality of source/drain regions 1216, and the gate electrode 1130 has a closed-loop shape in a plan view. Therefore, according to each of the integrated circuit devices 1100B, 1100C, and 1200, the area occupied by the planar transistor TR11A, TR11C, or TR12 on the substrate 102 may be reduced, and a structure having a good effect in down-scaling of the integrated circuit device 1100B, 1100C, or 1200 may be provided. Therefore, according to each of the integrated circuit devices 1100B, 1100C, and 1200, the planar transistor TR11A, TR11C, or TR12 capable of achieving intended performance with a minimum area in a highly reduced area may be provided.

In addition, according to each of the integrated circuit devices 1100B, 1100C, and 1200, a boundary region between the active region AC and the device isolation film 114 may not be affected by a voltage applied to the gate electrode 1130. Therefore, when a voltage lower than a threshold voltage is applied to the gate electrode 1130, issues, in which an unintended edge channel is formed in the vicinity of the interface between the active region AC and the device isolation film 114 or a hump phenomenon occurs due to the edge channel, may be prevented.

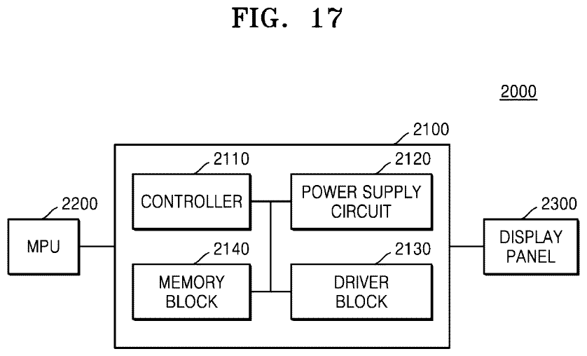

FIG. 17 is a schematic block diagram of a display device 2000 according to an embodiment.

Referring to FIG. 17, the display device 2000 includes a display driver integrated circuit (DDI) 2100. The DDI 2100 may include a controller 2110 (e.g., a controller circuit), a power supply circuit 2120, a driver block 2130 (e.g., a driver circuit), and a memory block 2140 (e.g., a memory device). The controller 2110 may receive and decode a command applied by a main processing unit (MPU) 2200 and may control respective blocks of the DDI 2100 to implement an operation according to the command. The power supply circuit 2120 may generate a driving voltage in response to control by the controller 2110. The driver block 2130 may drive a display panel 2300 by using the driving voltage generated by the power supply circuit 2120, in response to control by the controller 2110. The display panel 2300 may include a liquid-crystal display panel or a plasma display panel. The memory block 2140 may temporarily store commands input to the controller 2110 or control signals output from the controller 2110 or may store required data. The memory block 2140 may include memory, such as random-access memory (RAM) or read-only memory (ROM). Each of the power supply circuit 2120 and the driver block 2130 may include at least one of the recess channel transistors TRA, TRB, TRC, TRD, TR2, TR3, TR4, TR5, TR6, TR7, TR8, and TR9, which are respectively included in the integrated circuit devices 100A, 100B, 100C, 100D, 200, 300, 400, 500, 600, 700, 800, and 900 described with reference to FIGS. 1A to 12, and the planar transistors TR11A, TR11B, TR11C, and TR12, which are respectively included in the integrated circuit devices 1100A, 1100B, 1100C, and 1200.

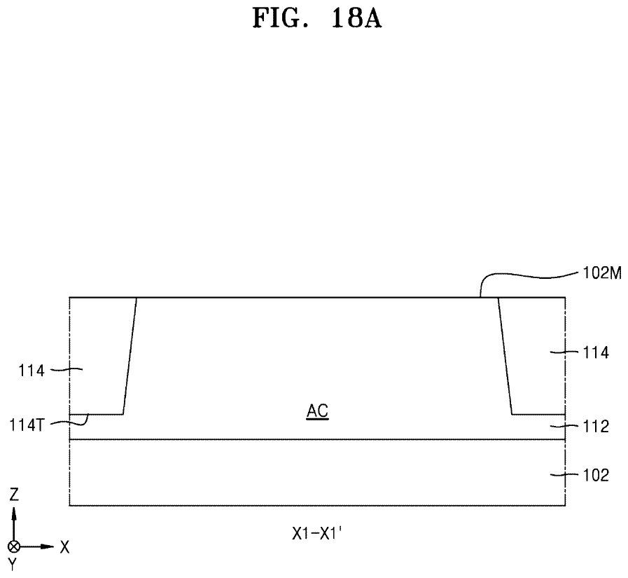

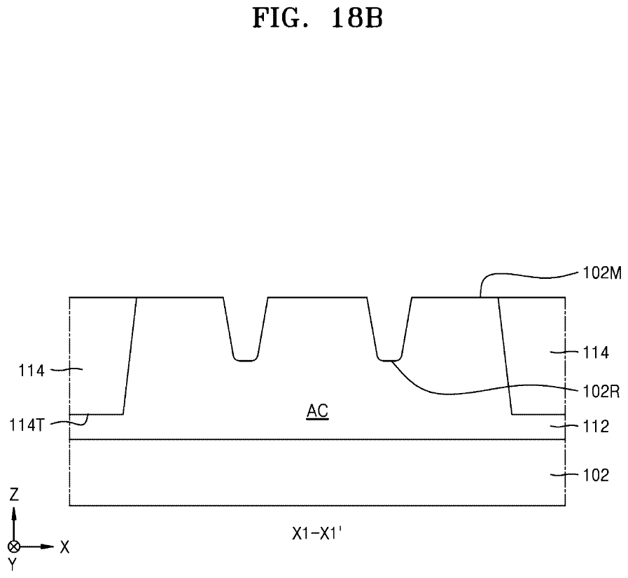

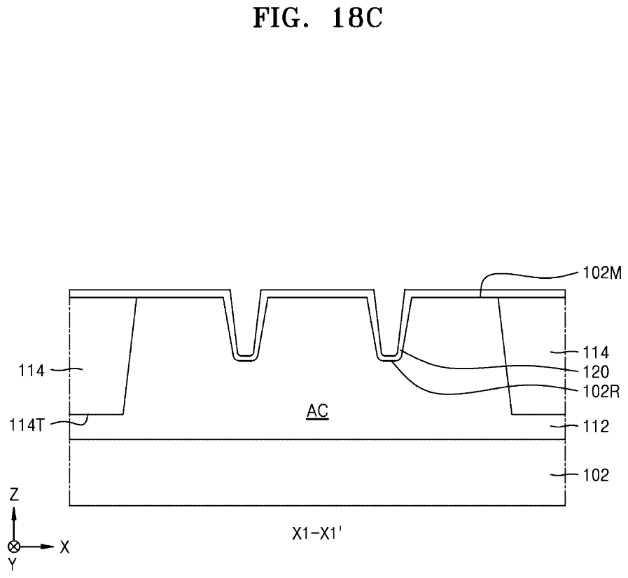

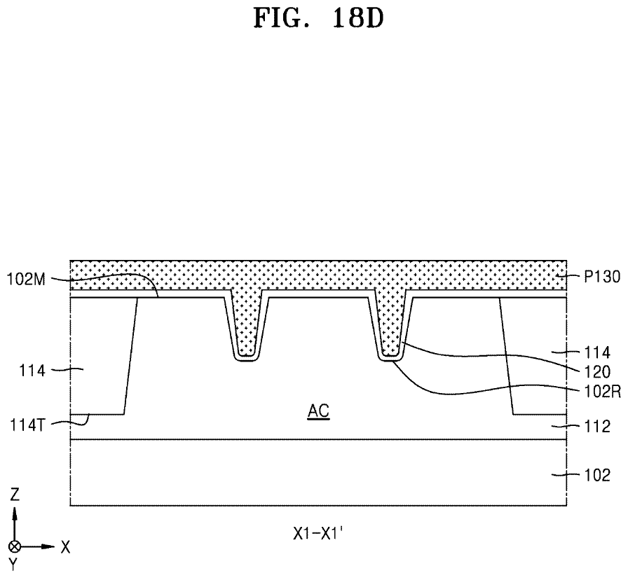

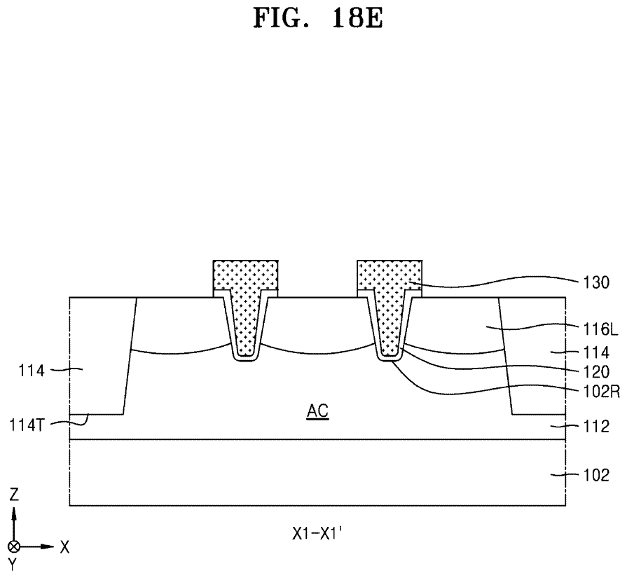

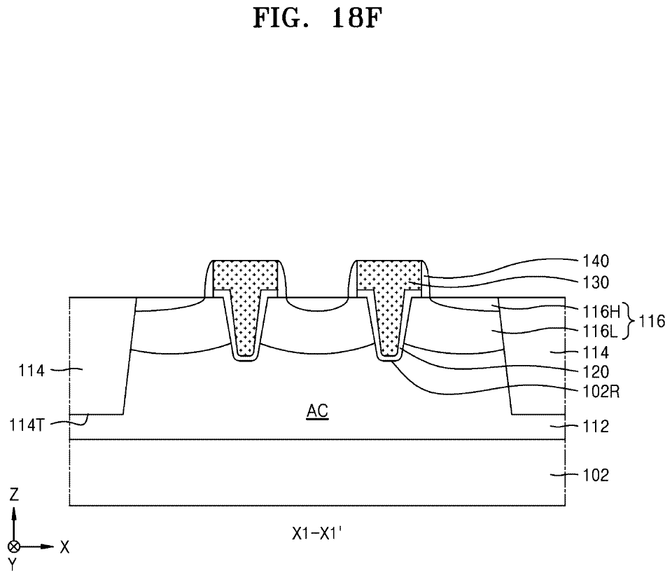

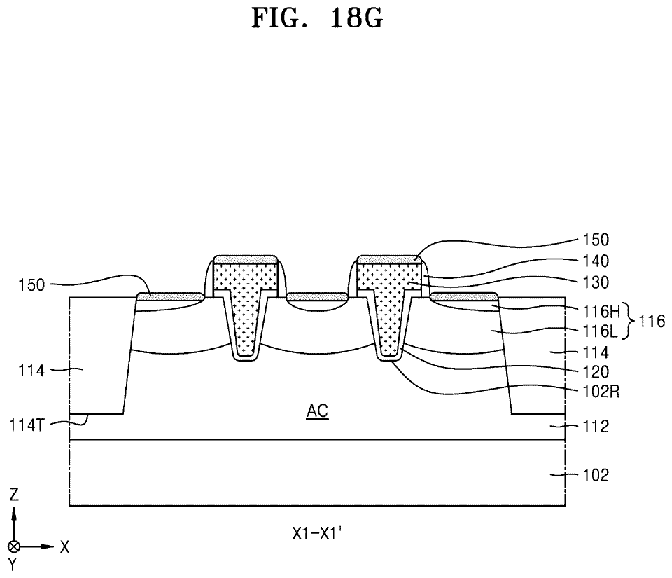

FIGS. 18A to 18G are cross-sectional views respectively illustrating a sequence of processes of a method of fabricating an integrated circuit device, according to embodiments. FIGS. 18A to 18G each illustrate components in a region corresponding to the cross-section taken along the line X1-X1′ of FIG. 1A, according to the sequence of processes. An example of a method of fabricating the integrated circuit device 100A shown in FIGS. 1A and 1B is described with reference to FIGS. 18A to 18G. In FIGS. 18A to 18G, the same reference numerals as in FIGS. 1A and 1B respectively denote the same members, and here, repeated descriptions thereof are omitted.

Referring to FIG. 18A, a well 112 of a first conductivity type may be formed by doping a portion of a substrate 102 with impurity ions. In an embodiment, phosphorus (P) ions are implanted into the substrate 102 to form the well 112 and set its first conductivity type to n-type.

Next, a trench region 114T may be formed by partially etching the substrate 102 from a main surface 102M of the substrate 102, and a device isolation film 114 may be formed by filling the trench region 114T. For example, the trench region 114T may be formed by removing portions of the substrate 102. An active region AC may be defined in the substrate 102 by the trench region 114T and the device isolation film 114.

In some embodiments, to form the trench region 114T in the substrate 102, a hardmask pattern may be formed on the substrate 102, and the substrate 102 may be etched by using the hardmask pattern as an etch mask. The hardmask pattern may have a structure in which an oxide film and a nitride film are sequentially stacked. A chemical vapor deposition (CVD) process may be used to form the device isolation film 114, but the inventive concept is not limited thereto.

Referring to FIG. 18B, a recess trench 102R may be formed in the active region AC by partially etching the substrate 102 in the active region AC from the main surface 102M of the substrate 102. As shown in FIG. 1A, the recess trench 102R may have a closed-loop shape in a plan view. For example, portions of the active region AC may be removed to form the recess trench 102R.

In some embodiments, the depth of the recess trench 102R in the vertical direction (the Z direction) may be variously adjusted as needed. In some embodiments, after forming the recess trench 102R, ions may be locally implanted into the active region AC through a lower surface of the recess trench 102R, resulting in formation of a drift ion-implanted region in a portion of the active region AC adjacent to the lower surface of the recess trench 102R. For example, when forming a recess channel transistor TRA (see FIGS. 1A and 1B) including a PMOS transistor is intended, p-type impurity ions may be implanted into the portion of the active region AC adjacent to the lower surface of the recess trench 102R to form the drift ion-implanted region.

Referring to FIG. 18C, in the resulting product of FIG. 18B, a gate dielectric film 120 may be formed to conformally cover an inner wall of the recess trench 102R and the main surface 102M of the substrate 102.A process including a thermal oxidation process, a CVD process, or a combination thereof may be used to form the gate dielectric film 120. In an embodiment, a thickness of the gate dielectric film 120 in this step is uniform or substantially uniform.

Referring to FIG. 18D, in the resulting product of FIG. 18C, a gate electrode layer P130 may be formed to cover the gate dielectric film 120. In some embodiments, the gate electrode layer P130 may include polysilicon. The gate electrode layer P130 may be formed on the gate dielectric film 120 to fill the remaining space of the recess trench 102R while covering the main surface 102M of the substrate 102 outside the recess trench 102R. For example, recesses in the gate dielectric film 120 may be filled with material of the gate electrode layer P130.

Referring to FIG. 18E, a gate electrode 130 may be formed by patterning the gate electrode layer P130, and the active region AC may be exposed by removing portions of the gate dielectric film 120, which are exposed around the gate electrode 130. As shown in FIG. 1A, the gate electrode 130 may have a closed-loop shape in a plan view. For example, the patterning may remove portions of the gate electrode layer P130.

Next, impurity ions of a second conductivity type that is opposite to the first conductivity type may be implanted into the gate electrode 130 and the active region AC. As a result, a lightly-doped region 116L may be formed in the active region AC. In some embodiments, when the second conductivity type is a p-type, boron (B) ions may be implanted into a portion of the well 112 to form the lightly-doped region 116L. In some embodiments, the lightly-doped region 116L may be formed in the manner of self-alignment by the gate electrode 130.

Referring to FIG. 18F, an insulating spacer 140 may be formed to cover respective sidewalls of the gate dielectric film 120 and the gate electrode 130, and impurity ions of the second conductivity type may be implanted into a portion of the lightly-doped region 116L at a relatively high concentration, thereby forming a heavily-doped region 116H. As a result, a source/drain region 116 may be formed in each of a first local region, which is surrounded by the gate electrode 130, of the active region AC and a second local region, which surrounds the gate electrode 130, of the active region AC. In an embodiment, an area or volume of the heavily-doped region 116H is smaller than an area or volume of the lightly-doped region 116L.

When the second conductivity type is a p-type, boron (B) ions may be implanted into the portion of the lightly-doped region 116L to form the heavily-doped region 116H. The heavily-doped region 116H may be formed in the manner of self-alignment by the insulating spacer 140.

Referring to FIG. 18G, by performing a salicide process on the resulting product of FIG. 12F, a plurality of metal silicide films 150 may be formed to cover the upper surface of the gate electrode 130 and the upper surface of the source/drain region 116. In an embodiment, the plurality of metal silicide films 150 are not formed on each of the insulating spacer 140 and the device isolation film 114.

Next, as shown in FIG. 1B, an interlayer dielectric 160 may be formed on the resulting product of FIG. 18G, followed by forming a plurality of source/drain contact plugs 172 and a plurality of gate contact plugs 174, which each pass through the interlayer dielectric 160 in the vertical direction (the Z direction) to be connected to a metal silicide film 150, and then, a plurality of wiring layers 180 may be formed on the interlayer dielectric 160, thereby fabricating the integrated circuit device 100A shown in FIGS. 1A and 1B. The plurality of wiring layers 180 may formed to contact the source/drain contact plugs 172.

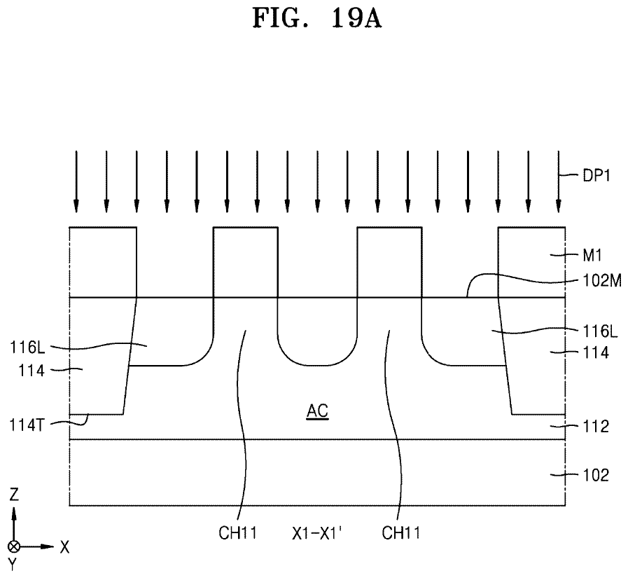

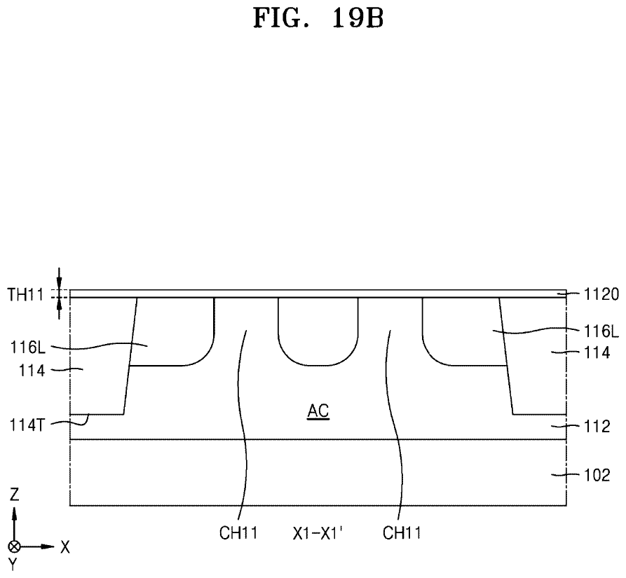

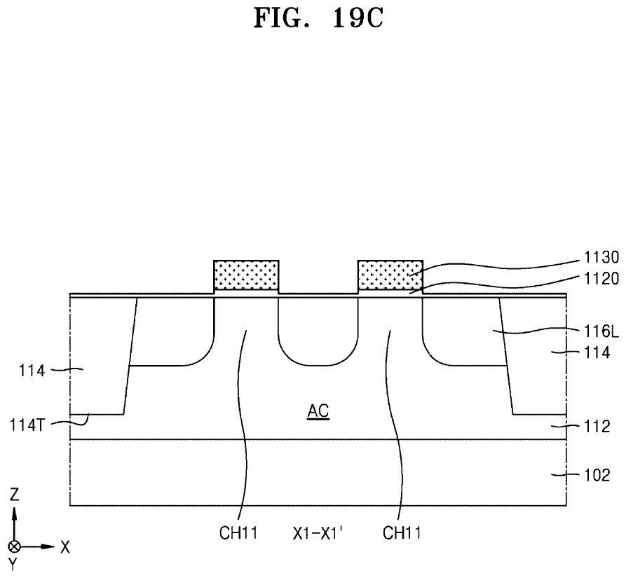

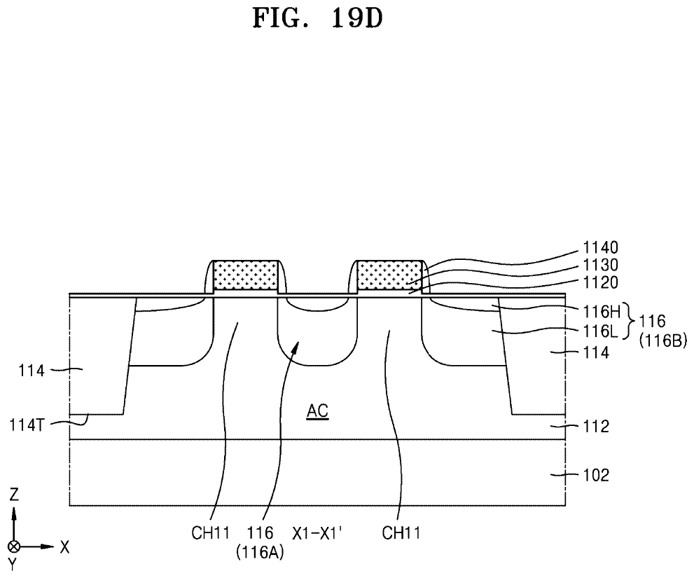

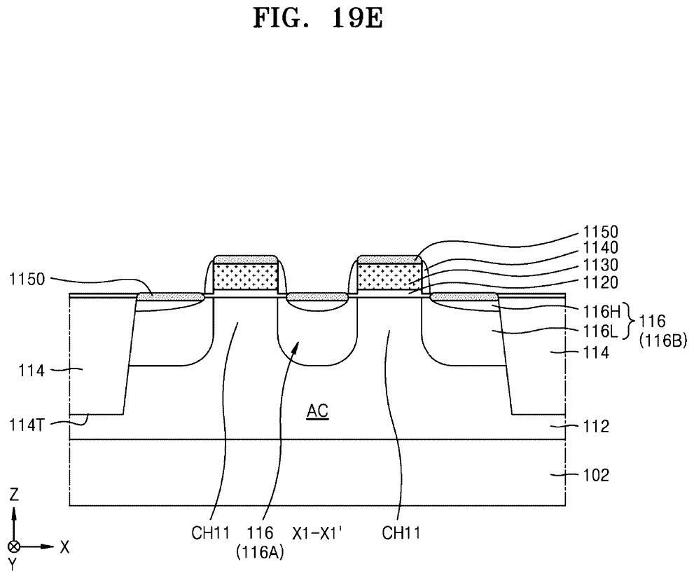

FIGS. 19A to 19E are cross-sectional views respectively illustrating a sequence of processes of a method of fabricating an integrated circuit device, according to embodiments. FIGS. 19A to 19E each illustrate components in a region corresponding to the cross-section taken along the line X1-X1′ of FIG. 13A, according to the sequence of processes. An example of a method of fabricating the integrated circuit device 1100A shown in FIGS. 13A and 13B is described with reference to FIGS. 19A to 19E. In FIGS. 19A to 19E, the same reference numerals as in FIGS. 1A to 18G respectively denote the same members, and here, repeated descriptions thereof are omitted.

Referring to FIG. 19A, in the same manner as that described with reference to FIG. 18A, a well 112 of a first conductivity type may be formed by doping a portion of a substrate 102 with impurity ions, and an active region AC may be defined by forming a device isolation film 114 in the substrate 102.

Next, a mask pattern M1 having openings to partially expose the active region AC may be formed on the substrate 102, followed by implanting impurity ions DP1 of a second conductivity type, which is opposite to the first conductivity type, into the active region AC exposed by the openings, by using the mask pattern M1 as an ion implantation mask, thereby forming a plurality of lightly-doped regions 116L of the second conductivity type in the well 112. In some embodiments, when the second conductivity type is a p-type, the impurity ions DP1 may include boron (B) ions. In the active region AC, a channel region CH11 may be defined by the plurality of lightly-doped regions 116L.

Referring to FIG. 19B, the mask pattern M1 may be removed from the resulting product of FIG. 19A, and then, a gate dielectric film 1120 may be formed to cover the active region AC and the device isolation film 114.

In some embodiments, the gate dielectric film 1120 may include a silicon oxide film. To form the gate dielectric film 1120, a CVD process or a combination of a thermal oxidation process and a CVD process may be used. In some embodiments, a thickness TH1 of the gate dielectric film 1120 may be, but is not limited to, about 400 Å to about 500 Å. In some embodiments, the gate dielectric film 1120 may be formed with a uniform thickness on the substrate 102.

Referring to FIG. 19C, a gate electrode 1130 may be formed on the gate dielectric film 1120 to cover the channel region CH11.

As shown in FIG. 13A, the gate electrode 1130 may be formed with a closed-loop shape in a plan view. To form the gate electrode 1130, a conductive layer (not shown) may be formed on the entire surface of the resulting product of FIG. 19B in which the gate dielectric film 1120 is formed, followed by patterning the conductive layer by a photolithography process, thereby leaving the gate electrode 1130 on the gate dielectric film 1120. In some embodiments, the conductive layer may include doped polysilicon. During the process of patterning the conductive layer, a portion, which is exposed around the gate electrode 1130, of the gate dielectric film 1120 may be removed by as much as a certain thickness. As a result, the portion, which is exposed around the gate electrode 1130, of the gate dielectric film 1120 may have a thickness less than that of a portion, which is covered by the gate electrode 1130, of the gate dielectric film 1120.

Referring to FIG. 19D, an insulating spacer 1140 may be formed on the gate dielectric film 1120 to cover sidewalls of the gate electrode 1130.

Referring to FIG. 19E, in the resulting product of FIG. 19C, impurity ions of the second conductivity type may be selectively implanted at a relatively high concentration into only the gate electrode 1130 and the plurality of lightly-doped regions 116L. As a result, a heavily-doped region 116H may be formed in an upper portion of each of the plurality of lightly-doped regions 116L. The impurity concentration in the heavily-doped region 116H may be greater than the impurity concentration in the lightly-doped region 116L. The plurality of lightly-doped regions 116L and a plurality of heavily-doped regions 116H may constitute a plurality of source/drain regions 116. The plurality of source/drain regions 116 may include a first source/drain region 116A and a second source/drain region 116B that are spaced apart from each other with the gate electrode 1130 therebetween. As shown in FIG. 13A, in a plan view, the first source/drain region 116A may be surrounded by the gate electrode 1130. In a plan view, the second source/drain region 116B may be arranged between the device isolation film 114 and the gate electrode 1130, and the gate electrode 1130 and the first source/drain region 116A may be surrounded by the second source/drain region 116B.

In some embodiments, as described with reference to FIG. 19D, to selectively implant the impurity ions of the second conductivity type at a relatively high concentration into only the gate electrode 1130 and the plurality of lightly-doped regions 116L, a local mask pattern may be formed on the entire surface of a resulting product in which the insulating spacer 1140 is formed. A first hole, which exposes the upper surface of the gate electrode 1130, and a plurality of second holes exposing portions, which cover the plurality of lightly-doped regions 116L, of the gate dielectric film 1120 may be formed in the local mask pattern. In some embodiments, the local mask pattern may include a hardmask pattern, a photoresist pattern, or a combination thereof.

Referring to FIG. 19E, in the resulting product of FIG. 19D, the upper surface of each of the plurality of source/drain regions 116 may be exposed by removing portions of the gate dielectric film 1120, and a silicide process may be performed, thereby forming a plurality of silicide films 1150 to cover the upper surface of the gate electrode 130 and the upper surface of the source/drain region 116.

Next, an interlayer dielectric 160 may be formed on the resulting product of FIG. 19E, as shown in FIG. 13B, followed by forming a plurality of source/drain contact plugs 172 and a plurality of gate contact plugs 174 to pass through the interlayer dielectric 160 in the vertical direction (the Z direction) to be connected to the metal silicide film 1150, and then, a plurality of wiring layers 180 may be formed on the interlayer dielectric 160, thereby fabricating the integrated circuit device 1100A shown in FIGS. 13A and 13B.

Heretofore, although examples of the methods of fabricating the integrated circuit device 100A shown in FIGS. 1A and 1B and the integrated circuit device 1100A shown in FIGS. 13A and 13B have been described with reference to FIGS. 18A to 18G and 19A to 19E, it will be understood by those of ordinary skill in the art that, by making various modifications and changes to the methods described with reference to FIGS. 18A to 18G and 19A to 19E without departing from the spirit and scope of the inventive concept, the integrated circuit devices 100B, 100C, 100D, 200, 300, 400, 500, 600, 700, 800, and 900 described with reference to FIGS. 2 to 12, the integrated circuit devices 1100B, 1100C, and 1200, or integrated circuit devices having various structures and variously modified and changed therefrom may be fabricated.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate including an active region defined by a device isolation film; and
a gate electrode disposed over the active region so as to be spaced apart from the device isolation film,
wherein the gate electrode has a closed-loop shape in a plan view.

2. The integrated circuit device of claim 1, further comprising a recess trench disposed in the active region so as to be spaced apart from the device isolation film, the recess trench extending in a vertical direction from a main surface of the substrate toward the inside of the substrate,
wherein the gate electrode comprises a buried electrode portion, which fills the recess trench, and a protruding electrode portion integrally connected to the buried electrode portion and protruding upwards from the main surface of the substrate, and
in a plan view, each of the buried electrode portion and the protruding electrode portion of the gate electrode is spaced apart from the device isolation film in a horizontal direction not to overlap the device isolation film in the vertical direction.

3. The integrated circuit device of claim 1, wherein the gate electrode is disposed over the substrate so as to be spaced apart from a main surface of the substrate in a vertical direction, and
in a plan view, the gate electrode is spaced apart from the device isolation film in a horizontal direction not to overlap the device isolation film in the vertical direction.

4. The integrated circuit device of claim 1, further comprising:
a first source/drain region surrounded by the gate electrode in a plan view; and
a second source/drain region disposed between the gate electrode and the device isolation film and surrounding the gate electrode, in a plan view, the second source/drain region having a closed-loop shape in a plan view.

5. The integrated circuit device of claim 4, wherein each of the first source/drain region and the second source/drain region comprises a lightly-doped region and a heavily-doped region that is surrounded by the lightly-doped region,
in at least one of the first source/drain region and the second source/drain region, the lightly-doped region comprises a drift region extending in a horizontal direction from the heavily-doped region toward the gate electrode, and
in a plan view, the drift region has a closed-loop shape.

6. The integrated circuit device of claim 4, wherein each of the first source/drain region and the second source/drain region comprises a lightly-doped region and a heavily-doped region that is surrounded by the lightly-doped region,
the lightly-doped region of the first source/drain region comprises a first drift region extending in the horizontal direction from the heavily-doped region of the first source/drain region toward the gate electrode,
the lightly-doped region of the second source/drain region comprises a second drift region extending in the horizontal direction from the heavily-doped region of the second source/drain region toward the gate electrode,
in a plan view, the first drift region has a closed-loop shape surrounding the heavily-doped region of the first source/drain region, and
in a plan view, the second drift region has a closed-loop shape surrounding the gate electrode and the first drift region.

7. The integrated circuit device of claim 1, further comprising:
a recess trench disposed in the active region so as to be spaced apart from the device isolation film and extending in a vertical direction from a main surface of the substrate toward the inside of the substrate; and
a gate dielectric film covering an inner wall of the recess trench,
wherein the gate electrode comprises a buried electrode portion, which is disposed on the gate dielectric film to fill the recess trench, and a protruding electrode portion integrally connected to the buried electrode portion and protruding upwards from the main surface of the substrate, and
a thickness of the gate dielectric film decreases away from the main surface of the substrate in the vertical direction.

8. The integrated circuit device of claim 1, further comprising:
a first source/drain region disposed in a first active region of the active region, the first active region being surrounded by the gate electrode in a plan view;
a second source/drain region disposed in a second active region of the active region, the second active region being disposed between the gate electrode and the device isolation film; and
a channel region disposed between the first source/drain region and the second source/drain region,
wherein, in a plan view, each of the second source/drain region and the channel region has a closed-loop shape.

9. The integrated circuit device of claim 1, wherein, in a plan view, the gate electrode has a quadrangular closed-loop shape with rounded corners, an elliptical closed-loop shape, or a circular closed-loop shape.

10. An integrated circuit device comprising:
a substrate including an active region defined by a device isolation film; and
a transistor disposed on the active region,
wherein the transistor comprises:
a first source/drain region disposed in a first active region that is a portion of the active region;
a gate electrode having a closed-loop shape surrounding the first source/drain region in a plan view; and
a second source/drain region, which has a closed-loop shape surrounding the gate electrode and the first source/drain region in a plan view and is disposed in a second active region of the active region, the second active region being spaced apart from the first active region.

11. The integrated circuit device of claim 10, wherein, in a plan view, the gate electrode is spaced apart from the device isolation film in a horizontal direction not to overlap the device isolation film in a vertical direction.

12. The integrated circuit device of claim 10, further comprising:
a recess trench disposed in the active region between the first source/drain region and the second source/drain region and extending in a vertical direction from a main surface of the substrate toward the inside of the substrate; and
a channel region disposed adjacent to a bottom portion of the recess trench and having a closed-loop shape in a plan view,
wherein the gate electrode comprises a buried electrode portion, which fills the recess trench, and a protruding electrode portion integrally connected to the buried electrode portion and protruding upwards from the main surface of the substrate.

13. The integrated circuit device of claim 12, wherein each of the first source/drain region and the second source/drain region comprises a lightly-doped region and a heavily-doped region that is surrounded by the lightly-doped region,
in at least one of the first source/drain region and the second source/drain region, the lightly-doped region comprises a drift region extending in a horizontal direction from the heavily-doped region toward the recess trench and the gate electrode, and
in a plan view, the drift region has a closed-loop shape.

14. The integrated circuit device of claim 10, wherein the gate electrode is disposed over the substrate so as to be spaced apart from a main surface of the substrate in a vertical direction, and
the transistor further comprises a channel region, which is disposed in the active region between the first source/drain region and the second source/drain region and has a closed-loop shape in a plan view.

15. The integrated circuit device of claim 14, wherein each of the first source/drain region and the second source/drain region comprises a lightly-doped region and a heavily-doped region that is surrounded by the lightly-doped region,
in at least one of the first source/drain region and the second source/drain region, the lightly-doped region comprises a drift region extending in a horizontal direction from the heavily-doped region toward the channel region, and
in a plan view, the drift region has a closed-loop shape.

16. The integrated circuit device of claim 10, wherein the transistor further comprises:
an outer gate electrode disposed over the active region so as to be spaced apart from the device isolation film and located between the device isolation film and the gate electrode in a plan view, the outer gate electrode having a closed-loop shape surrounding the second source/drain region in a plan view; and
a third source/drain region disposed between the device isolation film and the outer gate electrode and having a closed-loop shape surrounding the outer gate electrode in a plan view.

17. The integrated circuit device of claim 10, wherein, in a plan view, the gate electrode has a quadrangular closed-loop shape with rounded corners, an elliptical closed-loop shape, or a circular closed-loop shape.

18. The integrated circuit device of claim 10, wherein the transistor further comprises a plurality of additional gate electrodes disposed over the active region and spaced apart from the gate electrode in a horizontal direction,
the plurality of additional gate electrodes are spaced apart from each other in the horizontal direction, each of the plurality of additional gate electrodes having a closed-loop shape in a plan view, and
the gate electrode and the plurality of additional gate electrodes are connected to each other via a common gate terminal.

19. An integrated circuit device comprising:
a substrate including an active region defined by a device isolation film;
a gate electrode disposed over the active region and spaced apart from the device isolation film in a horizontal direction not to overlap the device isolation film in a vertical direction;
a first source/drain region disposed in a first active region, which is a portion of the active region, and surrounded by the gate electrode in a plan view;
a second source/drain region disposed in a second active region of the active region and spaced apart from the first source/drain region with the gate electrode therebetween in a plan view, the second active region being spaced apart from the first active region; and
a channel region disposed in the active region between the first source/drain region and the second source/drain region,
wherein each of the gate electrode, the second source/drain region, and the channel region has a closed-loop shape in a plan view.

20. The integrated circuit device of claim 19, wherein each of the first source/drain region and the second source/drain region comprises a lightly-doped region and a heavily-doped region that is surrounded by the lightly-doped region,
in at least one of the first source/drain region and the second source/drain region, the lightly-doped region comprises a drift region extending in the horizontal direction from the heavily-doped region toward the gate electrode, and
in a plan view, the drift region has a closed-loop shape.
